(19) United States
(12) Patent Application Publication
(10) Pub. No.: US 2025/0374731 A1
(43) Pub. Date: Dec. 4, 2025

(54) PIXEL AND DISPLAY APPARATUS INCLUDING THE SAME

(71) Applicant: Samsung Display Co., Ltd., Yongin-si (KR)

(72) Inventors: Taehoon Kwon, Yongin-si (KR); Mina Kim, Yongin-si (KR); Wonkyu Kwak, Yongin-si (KR); Dongsoo Kim, Yongin-si (KR); Kyunghoon Kim, Yongin-si (KR)

(21) Appl. No.: 19/182,184

(22) Filed: Apr. 17, 2025

(30) Foreign Application Priority Data
May 31, 2024 (KR) 10-2024-0071808

(51) Int. Cl. H10H 29/39; H10H 29/32

(52) U.S. Cl. CPC H10H 29/39; H10H 29/32

(57) ABSTRACT

A pixel includes a light-emitting diode, a first transistor connected between a first voltage line and the light-emitting diode, and configured to control a current supplied to the light-emitting diode, a second transistor connected between a data line and a first node connected to a first terminal of the first transistor, and including a 2-1 transistor connected between the data line and a fourth node, and a 2-2 transistor in series with the 2-1 transistor and connected between the fourth node and the first node, a third transistor connected between a second node connected to a gate of the first transistor and a third node connected to a second terminal of the first transistor, a fifth transistor connected between the first voltage line and the first node, and a sixth transistor connected between the third node and the light-emitting diode.

### CROSS-REFERENCE TO RELATED APPLICATION

The present application claims priority to, and the benefit of, Korean Patent Application No. 10-2024-0071808, filed on May 31, 2024, in the Korean Intellectual Property Office, the disclosure of which is incorporated by reference herein in its entirety.

### BACKGROUND

### 1. Field

One or more embodiments relate to a pixel and a display apparatus including the same.

### 2. Description of the Related Art

Recently, display apparatuses have been used for various purposes. Also, as the thickness and weight of the display apparatuses have been decreased, their range of applications has increased.

As the display apparatuses have been widely used, various methods of designing the shapes of the display apparatuses have been used and the number of functions linked to or associated with the display apparatuses has increased.

### SUMMARY

One or more embodiments include a display apparatus with improved display quality, although this is provided merely as an example, and thus does not pose a limitation on the scope of the disclosure.

Additional aspects will be set forth in part in the description which follows and, in part, will be apparent from the description, or may be learned by practice of the presented embodiments of the disclosure.

According to one or more embodiments, a pixel includes a light-emitting diode, a first transistor connected between a first voltage line and the light-emitting diode, and configured to control a current supplied to the light-emitting diode, a second transistor connected between a data line and a first node connected to a first terminal of the first transistor, and including a 2-1 transistor connected between the data line and a fourth node, and a 2-2 transistor in series with the 2-1 transistor and connected between the fourth node and the first node, a third transistor connected between a second node connected to a gate of the first transistor and a third node connected to a second terminal of the first transistor, a fifth transistor connected between the first voltage line and the first node, and a sixth transistor connected between the third node and the light-emitting diode.

A gate-on voltage may be supplied to a gate of the 2-1 transistor at some time while a gate-on voltage is supplied to a gate of the 2-2 transistor.

A gate-on voltage of a second level may be supplied to a gate of the third transistor at some time while a gate-off voltage of a first level is supplied a gate of the fifth transistor and to a gate of the sixth transistor, and at some time while a gate-on voltage of a first level is supplied to a gate of the 2-1 transistor to a gate of the 2-2 transistor.

The gate of the 2-1 transistor may be connected to a 1-1 gate line, and the gate of the 2-2 transistor may be connected to a 1-2 gate line.

The gate of the fifth transistor and the gate of the sixth transistor may be connected to a fifth gate line.

The pixel may further include an eighth transistor configured to supply a bias voltage to the first node, wherein a gate of the eighth transistor is connected to a fourth gate line.

The pixel may further include a seventh transistor connected between a pixel electrode of the light-emitting diode and a second voltage line, wherein a gate of the seventh transistor is connected to the fourth gate line.

The pixel may further include a first capacitor connected between the first voltage line and the second node, and a fourth transistor connected between the second node and a third voltage line.

The pixel may further include a second capacitor connected between the first voltage line and the fourth node.

The fourth transistor may be connected to a second gate line, wherein the third transistor is connected to a third gate line.

According to one or more embodiments, a display apparatus includes pixels, wherein the pixels include a light-emitting diode, a first transistor connected between a first voltage line and the light-emitting diode, and configured to control a current supplied to the light-emitting diode, a second transistor connected between a data line and a first node connected to a first terminal of the first transistor, and including a 2-1 transistor connected between the data line and a fourth node, and connected to a 1-1 gate line for providing a 1-1 gate signal, and a 2-2 transistor in series with the 2-1 transistor, connected between the fourth node and the first node, and connected to a 1-2 gate line for providing a 1-2 gate signal, a third transistor connected between a second node connected to a gate of the first transistor and a third node connected to a second terminal of the first transistor, a fifth transistor connected between the first voltage line and the first node, and a sixth transistor connected between the third node and the light-emitting diode.

The 1-2 gate signal may include a signal temporally shifted from the 1-1 gate signal.

The pixels may include a first capacitor connected between the first voltage line and the second node, an eighth transistor configured to supply a bias voltage to the first node, a seventh transistor connected between a pixel electrode of the light-emitting diode and a second voltage line, and a fourth transistor connected between the second node and a third voltage line.

The pixels may further include a second capacitor connected between the first voltage line and the fourth node.

A gate of the fifth transistor and a gate of the sixth transistor may be connected to a fifth gate line for transmitting a fifth gate signal.

A gate of the eighth transistor and a gate of the seventh transistor may be connected to a fourth gate line for transmitting a fourth gate signal.

The fourth transistor may be connected to a second gate line for transmitting a second gate signal.

The third transistor may be connected to a third gate line for transmitting a third gate signal.

The display apparatus may further include a gate-driving circuit for outputting a fifth gate signal of gate-off voltage to the fifth gate line in a non-emission section of a frame section including an emission section and the non-emission section, for outputting a third gate signal of gate-on voltage to the third gate line in a first period of the non-emission section, for outputting a 1-1 gate signal of gate-on voltage to the 1-1 gate line in a second period during the first period, and for outputting a 1-2 gate signal of gate-on voltage to the 1-2 gate line in a third period during the first period.

The second period and the third period may at least partially temporally overlap.

### BRIEF DESCRIPTION OF THE DRAWINGS

The above and other aspects of embodiments of the disclosure will be more apparent from the following description taken in conjunction with the accompanying drawings, in which:

FIGS. 1A and 1B are each a plan view schematically illustrating a display apparatus according to one or more embodiments;

FIG. 2 is a view schematically illustrating a display apparatus according to one or more embodiments;

FIG. 3 is an equivalent circuit diagram of a pixel according to one or more embodiments;

FIGS. 4A and 4B are each a conceptual diagram illustrating a method of driving a display apparatus according a driving frequency;

FIG. 5 is a diagram illustrating signals provided to a pixel;

FIG. 6 is a diagram schematically illustrating a gate-driving circuit according to one or more embodiments;

FIG. 7 is a diagram schematically illustrating some stages of a gate-driving circuit and gate lines connected to a pixel according to one or more embodiments;

FIG. 8 is a diagram illustrating a pixel arranged in an ith row in a display according to one or more embodiments;

FIG. 9 is a diagram illustrating gate signals output by a gate-driving circuit according to one or more embodiments;

FIG. 10 is a diagram schematically illustrating some stages of a gate-driving circuit and gate lines connected to a pixel according to one or more embodiments;

FIG. 11 is a diagram illustrating a pixel arranged in an ith row in a display according to one or more embodiments;

FIG. 12 is a diagram illustrating gate signals output by a gate-driving circuit according to one or more embodiments;

FIG. 13 is a cross-sectional view of a part of a display apparatus according to one or more embodiments;

FIG. 14 is an arrangement view schematically illustrating positions of devices arranged in a pixel circuit of a display apparatus according to one or more embodiments;

FIGS. 15 to 24 are each an arrangement view schematically illustrating, by layer, devices arranged in a pixel circuit of a display apparatus according to one or more embodiments

FIG. 25 is a block diagram of an electronic device according to one or more embodiments; and

FIG. 26 is schematic diagrams of electronic devices according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

In embodiments below, the term “ON” used in relation to a state of a device refers to an active state of the device, and the term “OFF” refers to an inactive sate of the device. The term “ON” used in relation to a signal received by a device refers to a signal activating the device and the term “OFF” refers to a signal inactivating the device. A device may be activated by a high-level voltage or a low-level voltage. For example, a P-channel transistor (P-type transistor) may be activated by a low-level voltage, and an N-channel transistor (N-type transistor) may be activated by a high-level voltage. Accordingly, it should be understood that an “ON” voltage related to the P-type transistor and an “ON” voltage related to the N-type transistor have opposite voltage levels from each other (low voltage vs. high voltage).

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

A display apparatus according to embodiments may include an apparatus for displaying moving images or still images and may be used as a display screen of various products including televisions, notebook computers, monitors, advertisement boards, Internet of things (IoT) as well as portable electronic apparatuses including mobile phones, smart phones, tablet personal computers (PC), mobile communication terminals, electronic organizers, electronic books, portable multimedia players (PMP), navigations, and ultra mobile personal computers (UMPC). In addition, the display apparatus according to one or more embodiments may be used in wearable devices including smartwatches, watchphones, glasses-type displays, and head-mounted displays (HMD). The display apparatus may be used as instrument panels for automobiles, center fascias for automobiles, or center information displays (CID) arranged on a dashboard, room mirror displays that replace side mirrors of automobiles, and displays arranged on the backside of front seats as an entertainment for back seats of automobiles. The display apparatus may be a flexible apparatus.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

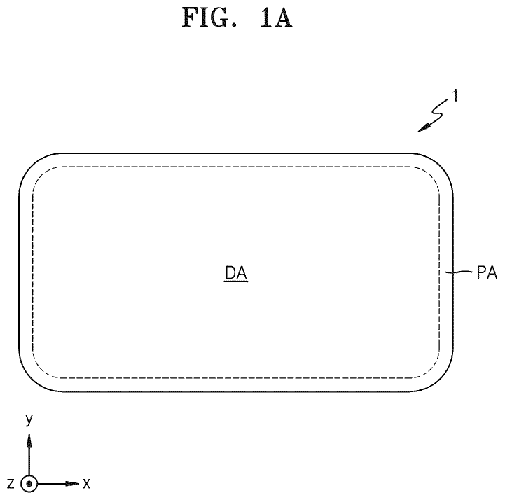

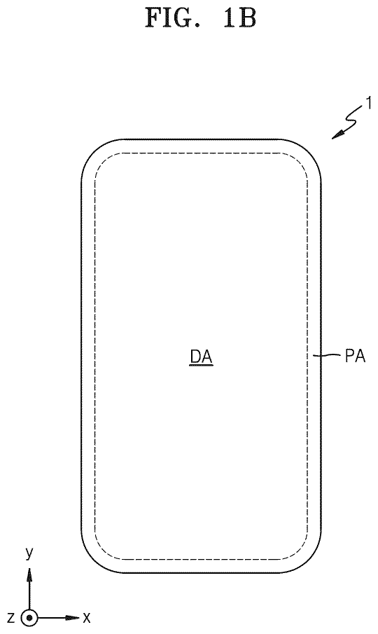

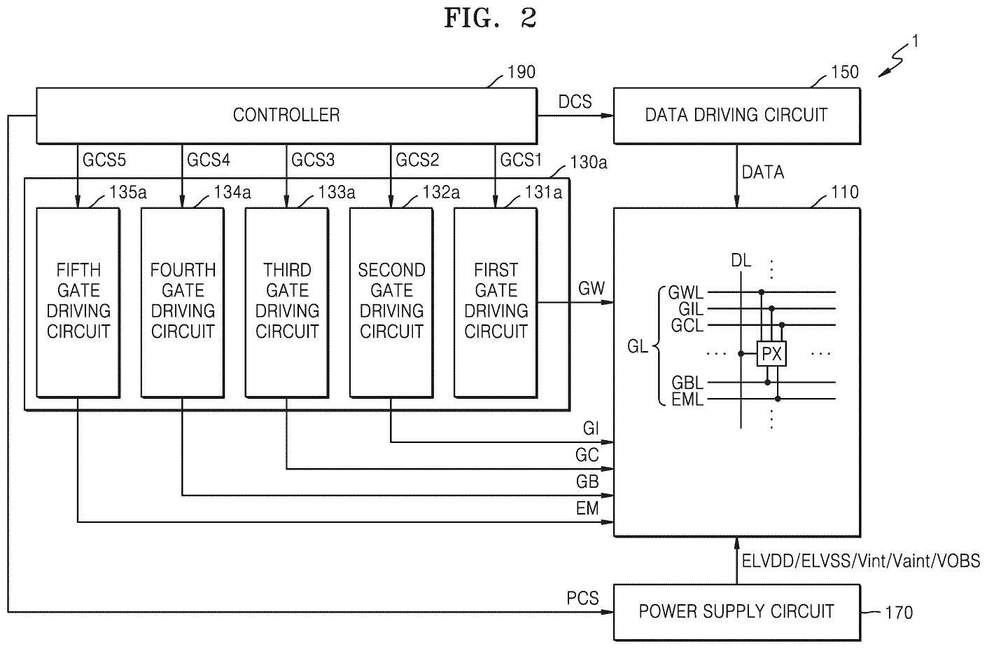

FIGS. 1A and 1B are each a plan view schematically illustrating a display apparatus according to one or more embodiments. FIG. 2 is a plan view schematically illustrating a display panel included in a display apparatus according to one or more embodiments.

Referring to FIGS. 1A and 1B, a display apparatus 1 may include a display area DA and a peripheral area PA outside the display area DA. The display area DA may be entirely surrounded by the peripheral area PA (e.g., in plan view).

In plan view, the display area DA may have a rectangular shape. In one or more other embodiments, the display area DA may have a polygonal shape, such as a triangular shape, an octagonal shape, a hexagonal shape, etc. or an atypical shape such as a circular shape, an elliptical shape, etc. The display area DA may have a round corner. In one or more embodiments, the display apparatus 1 may include the display area DA having a length in an x direction that is longer than a length in a y direction as illustrated in FIG. 1A. In one or more other embodiments, the display apparatus 1 may include the display area DA having a length in the y direction that is longer than the length in the x direction as illustrated in FIG. 1B.

Referring to FIG. 2, the display apparatus 1 according to one or more embodiments may include a display 110 (e.g., a pixel unit), a gate-driving circuit 130a, a data-driving circuit 150, a power supply circuit 170, and a controller 190.

The display 110 may be provided in the display area DA. In the peripheral area PA, various conductive lines transmitting electrical signals to be applied to the display area DA, outer circuits electrically connected to pixel circuits, and pads to which a printed circuit board or a driver integrated circuit (IC) chip is attached may be arranged. For example, the gate-driving circuit 130a, the data-driving circuit 150, the power supply circuit 170, and the controller 190 may be arranged in the peripheral area PA.

A plurality of pixels PX may be arranged in the display 110. The pixels PX may be repetitively arranged according to a certain pattern in the x direction (row direction) and the y direction (column direction). The pixels PX may have various arrangements, such as a stripe arrangement, a PenTile® arrangement (PenTile® being a registered trademark of Samsung Display Co., Ltd., Republic of Korea), a diamond arrangement, a mosaic arrangement, etc. to implement an image. Each pixel PX of the display 110 may include, as a display element, an organic light-emitting diode OLED, and the organic light-emitting diode OLED may be connected to the pixel circuit. The pixels PX may each emit, for example, red, green, blue, or white light through the organic light-emitting diode OLED. For example, the pixels PX may include a first pixel for emitting first color light, a second pixel for emitting second color light, and a third pixel for emitting third color light. For example, the first pixel may be a green pixel, the second pixel may be a red pixel, and the third pixel may be a blue pixel.

In the display 110, gate lines GL may be arranged apart from each other at regular distances in the y direction (for example, the column direction). Each of the gate lines GL may extend in the x direction (for example, the row direction) and may be connected to the pixels PX arranged in the same row (row line).

In the display 110, data lines DL may be arranged apart from each other at regular distances in the x direction. Each of the data lines DL may extend in the y direction and may be connected to the pixels PX arranged in the same column (column line). Each of the data lines DL may transmit a data signal DATA to each of the pixels PX in the same column in synchronization with a gate signal.

The gate-driving circuit 130a may be connected to the gate lines GL, may generate a gate signal in response to a control signal from the controller 190, and may sequentially provide the gate signal to the gate lines GL. The gate line GL may be connected to a gate of a transistor included in the pixel PX. The gate signal may be a gate control signal, which controls turning-on and turning-off of a transistor including a gate electrically connected to the gate line GL. The gate signal may be a signal including a gate-on voltage at which a transistor may be turned on and a gate-off voltage at which a transistor may be turned off.

Referring to FIG. 2, in one or more embodiments, the gate-driving circuit 130a may include gate-driving circuits. For example, the gate-driving circuit 130a may include a first gate-driving circuit 131a, a second gate-driving circuit 132a, a third gate-driving circuit 133a, a fourth gate-driving circuit 134a, and a fifth gate-driving circuit 135a. In some cases, some gate-driving circuits may be integrated.

The gate lines may include first gate lines GWL electrically connected to the first gate-driving circuit 131a, second gate lines GIL electrically connected to the second gate-driving circuit 132a, third gate lines GCL electrically connected to the third gate-driving circuit 133a, fourth gate lines GBL electrically connected to the fourth gate-driving circuit 134a, and fifth gate lines EML electrically connected to the fifth gate-driving circuit 135a.

The first gate-driving circuit 131a may be electrically connected to the first gate lines GWL and may sequentially supply a first gate signal GW to the first gate lines GWL in response to a first control signal GCS1. The second gate-driving circuit 132a may be electrically connected to the second gate lines GIL, and may sequentially supply a second gate signal GI to the second gate lines GIL in response to a second control signal GCS2. The third gate-driving circuit 133a may be electrically connected to the third gate lines GCL, and may sequentially supply a third gate signal GC to the third gate lines GCL in response to a third control signal GCS3. The fourth gate-driving circuit 134a may be electrically connected to the fourth gate lines GBL, and may sequentially supply a fourth gate signal GB to the fourth gate lines GBL in response to a fourth control signal GCS4. The fifth gate-driving circuit 135a may be electrically connected to the fifth gate lines EML, and may sequentially supply a fifth gate signal EM to the fifth gate lines EML in response to the fifth control signal GCS5.

The data-driving circuit 150 may be connected to the data lines DL, and may provide the data signal DATA to the data lines DL in response to a sixth control signal DCS from the controller 190. The data signal DATA provided to the data lines DL may be provided to the pixel PX to which the gate signal is provided. The data-driving circuit 150 may convert input image data having a gradation input from the controller 190 into the data signal DATA in the form of a voltage or current.

The power supply circuit 170 may generate voltages necessary for the driving of the pixel PX in response to a seventh control signal PCS from the controller 190. The power supply circuit 170 may generate a first power voltage ELVDD and a second power voltage ELVSS, and may supply the same to the pixels PX. The first power voltage ELVDD may be a high-level voltage supplied to a first electrode (a pixel electrode or an anode) of a display element included in the pixel PX. The second power voltage ELVSS may be a low-level voltage supplied to a second electrode (an opposite electrode or a cathode) of the display element included in the pixel PX. The power supply circuit 170 may generate a bias voltage VOBS, an initialization voltage Vint, and an initialization voltage Vaint, and may supply the same to the pixels PX.

A voltage level of the first power voltage ELVDD may be higher than a voltage level of the second power voltage ELVSS. A voltage level of the bias voltage VOBS may be lower than the voltage level of the first power voltage ELVDD. A voltage level of the initialization voltage Vint may be lower than the voltage level of the second power voltage ELVSS. A voltage level of the initialization voltage Vaint may be higher than the voltage level of the initialization voltage Vint. The voltage level of the initialization voltage Vaint may be identical to the voltage level of the second power voltage ELVSS, or may be higher than the voltage level of the second power voltage ELVSS.

The controller 190 may generate the first to seventh control signals GCS1, GCS2, GCS3, GCS4, GCS5, DCS, and PCS based on input signals input from the outside, and may provide the same to the first to fifth gate-driving circuits 131a, 132a, 133a, 134a, and 135a, the data-driving circuit 150, and the power supply circuit 170. The firth to fifth control signals GCS1, GCS2, GCS3, GCS4, and GCS5 output to the gate-driving circuit 130a may include clock signals and a gate initiation signal. The sixth control signal DCS output to the data-driving circuit 150 may include a data initiation signal and the clock signals.

The display apparatus 1 may include a display panel, and the display panel may include a substrate. The pixels PX may be arranged in the display area DA of the substrate. A part of or the entire gate-driving circuit 130a may be directly formed in the peripheral area PA in the process of forming the transistor constituting the pixel circuit in the display area DA of the substrate. The data-driving circuit 150, the power supply circuit 170, and the controller 190 may be formed in the form of separate integrated circuit chips or a single integrated circuit chip, and may be located on a flexible printed circuit board (FPCB) electrically connected to a pad arranged on one side of the substrate. In one or more other embodiments, the data-driving circuit 150, the power supply circuit 170, and the controller 190 may be directly located on the substrate in a chip-on-glass (GOC) or chip-on-plastic (COP) manner.

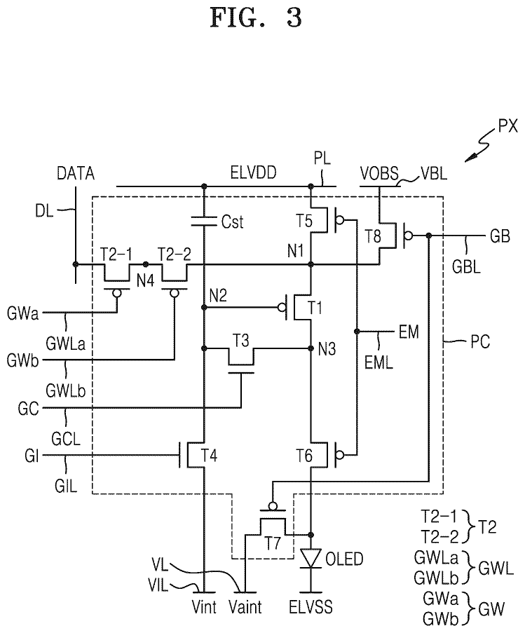

FIG. 3 is an equivalent circuit diagram of the pixel of FIG. 2 according to one or more embodiments.

Referring to FIG. 3, the pixel PX may include the organic light-emitting diode OLED and a pixel circuit PC electrically connected to the organic light-emitting diode OLED. The pixel circuit PC may include a first transistor T1, a second transistor T2, a third transistor T3, a fourth transistor T4, a fifth transistor T5, a sixth transistor T6, a seventh transistor T7, an eighth transistor T8, and a first capacitor Cst. The pixel circuit PC may be electrically connected to the data line DL, the first gate line GWL, the second gate line GIL, the third gate line GCL, the fourth gate line GBL, and the fifth gate line EML. The fifth gate line EML may be referred to as an emission control line, and the fifth gate signal EM transmitted through the fifth gate line EML may be referred to as an emission control signal. In addition, the pixel circuit PC may be electrically connected to a node initialization voltage line VIL (e.g., a third voltage line), an initialization voltage line VL (e.g., a second voltage line), and a first power supply line PL (e.g., a first voltage line).

In FIG. 3, the third transistor T3 and the fourth transistor T4 from among the first to eighth transistors T1 to T8 may be N-type transistors, and the others may be P-type transistors. According to types (N-type or P-type) and operating conditions of the transistor, a first terminal of the transistor may be a source electrode or a drain electrode, and the second terminal may be an electrode different from the first terminal. For example, when the first terminal is a source electrode, the second terminal may be a drain electrode. The gate of the transistor may be a gate electrode.

The first transistor T1 may be connected between the first power supply line PL and the organic light-emitting diode OLED. The first transistor T1 may be connected between a first node N1 and a third node N3. The first transistor T1 may be connected to the first power supply line PL via the fifth transistor T5, and may be electrically connected to the organic light-emitting diode OLED via the sixth transistor T6. The first transistor T1 may include a gate connected to a second node N2, a first terminal connected to the first node N1, and a second terminal connected to the third node N3. The first power supply line PL may transmit the first power voltage ELVDD to the first transistor T1. The first transistor T1 may function as a driver transistor and may provide a driving current to the organic light-emitting diode OLED by receiving the data signal DATA according to a switching operation of the second transistor T2.

The second transistor T2 (a data write transistor) may be connected between the data line DL and the first node N1. The second transistor T2 may be connected to the first power supply line PL via the fifth transistor T5. The second transistor T2 may include a pair of a 2-1 transistor T2-1 and a 2-2 transistor T2-2, which are sequentially control by the first gate signal GW as described in detail below. Gates of the 2-1 transistor T2-1 and the 2-2 transistor T2-2 may be respectively connected to separate gate lines. The first gate line GWL may include a 1-1 gate line GWLa and a 1-2 gate line GWLb. A node between the 2-1 transistor T2-1 and the 2-2 transistor T2-2 may be defined as a fourth node N4. The 2-1 transistor T2-1 may include a gate connected to the 1-1 gate line GWLa, a first terminal connected to the data line DL, and a second terminal connected to the fourth node N4. The 2-2 transistor T2-2 may include a gate connected to the 1-2 gate line GWLb, a first terminal connected to the fourth node N4, and a second terminal connected to the first node N1. The second transistor T2 may be turned on in response to the first gate signal GW transmitted through the first gate line GWL, and may perform the switching operation for transmitting the data signal DATA transmitting through the data line DL to the first node N1. For example, the 2-1 transistor T2-1 may be turned on in response to a 1-1 gate signal GWa transmitted through the 1-1 gate line GWLa, and the 2-2 transistor T2-2 may be turned on in response to a 1-2 gate signal GWb transmitted through the 1-2 gate line GWLb. When the 2-1 transistor T2-1 and the 2-2 transistor T2-2 are concurrently or substantially simultaneously turned on, the switching operating for transmitting the data signal DATA to the first node N1 may be performed.

The third transistor T3 (a compensation transistor) may be connected between the second node N2 and the third node N3. The third transistor T3 may be electrically connected to the organic light-emitting diode OLED via the sixth transistor T6. The third transistor T3 may include a gate connected to the third gate line GCL, a first terminal connected to the second node N2, and a second terminal connected to the third node N3. The third transistor T3 may be turned on in response to the third gate signal GC transmitted through the third gate line GCL and may compensate for a threshold voltage of the first transistor T1 through diode-connection of the first transistor T1.

The fourth transistor T4 (a node initialization transistor) may be connected between the second node N2 and the node initialization voltage line VIL. The fourth transistor T4 may include a gate connected to the second gate line GIL, a first terminal connected to the second node N2, and a second terminal connected to the node initialization voltage line VIL. The fourth transistor T4 may be turned on in response to the second gate signal GI transmitted through the second gate line GIL, and may initialize the gate of the first transistor T1 by transmitting the initialization voltage Vint to the gate of the first transistor T1.

The fifth transistor T5 (a first emission control transistor) may be connected between the first power supply line PL and the first node N1. The sixth transistor T6 (a second emission control transistor) may be connected between the third node N3 and the organic light-emitting diode OLED. The fifth transistor T5 may include a gate connected to the fifth gate line EML, a first terminal connected to the first power supply line PL, and a second terminal connected to the first node N1. The sixth transistor T6 may include a gate connected to the fifth gate line EML, a first terminal connected to the third node N3, and a second terminal connected to the organic light-emitting diode OLED. When the fifth transistor T5 and the sixth transistor T6 are concurrently or substantially simultaneously turned on in response to the fifth gate signal EM transmitted through the fifth gate line EML, the driving voltage may flow in the organic light-emitting diode OLED.

The seventh transistor T7 (an initialization transistor) may be connected between the organic light-emitting diode OLED and the initialization voltage line VL. The seventh transistor T7 may include a gate connected to the fourth gate line GBL, a first terminal connected to the second terminal of the sixth transistor T6 and the pixel electrode of the organic light-emitting diode OLED, and a second terminal connected to the initialization voltage line VL. The seventh transistor T7 may be turned on in response to the fourth gate signal GB transmitted through the fourth gate line GBL, and may initialize the pixel electrode of the organic light-emitting diode OLED by transmitting the initialization voltage Vaint to the pixel electrode of the organic light-emitting diode OLED. The eighth transistor T8 may be turned on concurrently or substantially simultaneously with the seventh transistor T7 in response to the fourth gate signal GB.

The seventh transistor T7 (a bias transistor) may be connected between the first node N1 and a bias voltage line VBL. The seventh transistor T7 may include a gate connected to the fourth gate line GBL, a first terminal connected to the bias voltage line VBL, and a second terminal connected to the first node N1. The seventh transistor T7 may be turned on in response to the fourth gate signal GB transmitted through the fourth gate line GBL, and may apply the bias voltage VOBS to the first terminal of the first transistor T1 to preset a voltage suitable for a subsequent operation of the first transistor T1 to the first terminal.

The first capacitor Cst may include a first electrode connected to the gate of the first transistor T1, and a second electrode connected to the first power supply line PL. The first capacitor Cst may store and maintain a voltage corresponding to a voltage difference between both ends of the gate of the first transistor T1 and the first power supply line PL to maintain a voltage applied to the gate of the first transistor T1.

When the pixel PX illustrated in FIG. 3 is a red pixel, the initialization voltage line VL may be a first initialization voltage line, and the initialization voltage Vaint may be a first initialization voltage. When the pixel PX illustrated in FIG. 3 is a green pixel, the initialization voltage line VL may be a second initialization voltage line, and the initialization voltage Vaint may be a second initialization voltage.

The organic light-emitting diode OLED may include a pixel electrode and an opposite electrode, and the second power voltage ELVSS may be applied to the opposite electrode. The organic light-emitting diode OLED may emit light by receiving the driving current from the first transistor T1 to display an image.

Although FIG. 3 illustrates that the pixel circuit PC includes eight transistors and one capacitor, the disclosure is not limited thereto. The number of transistors and capacitors included in the pixel circuit PC and the circuit design may vary.

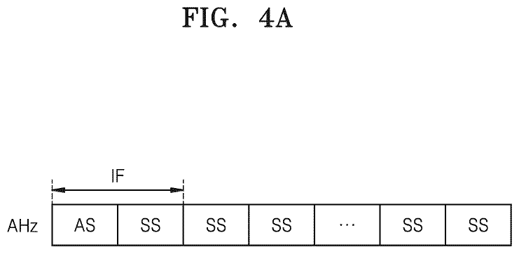

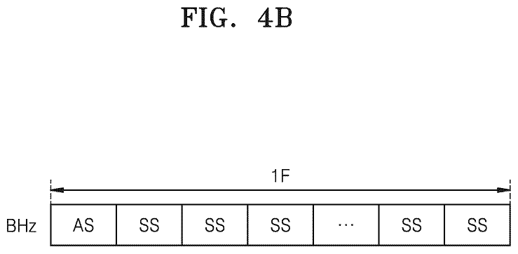

FIGS. 4A and 4B are each a conceptual diagram illustrating a method of driving a display apparatus according a driving frequency.

Referring to FIGS. 4A and 4B, in one or more embodiments, the display apparatus 1 (FIG. 2) may support a variable refresh rate (VRR). A refresh rate refers to a frequency of a data signal being substantially written to the driving transistor of the pixel PX. The refresh rate may also be referred to as a screen scan rate or a screen play rate, and may represent the number of frames played per second. In one or more embodiments, the refresh rate may be an output frequency of the gate-driving circuit 130a (FIG. 2) and/or the data-driving circuit 150 (FIG. 2). A frequency corresponding to the refresh rate may be a driving frequency. The display apparatus 1 may an output frequency of the gate-driving circuit 130a (FIG. 3) and an output frequency of the data-driving circuit 150 according to the driving frequency.

The display apparatus 1 supporting VRR may change the driving voltage within a range between a maximum driving frequency and a minimum driving frequency for operation. For example, when the VRR is about 60 Hz, a gate signal for writing a data signal from the gate-driving circuit 130a about 60 times per second may be provided to each horizontal line (row). The display apparatus 1 may display an image by varying the driving frequency according to the refresh rate.

The pixel PX may display an image per each frame section. One frame section 1F may include a non-emission section in which the pixel PX does not emit light and an emission section in which the pixel PX emits light.

According to the driving frequency, one frame section may include a first scan period AS, or a first scan period AS and at least one second scan period SS. For example, as illustrated in FIG. 4A, in the display apparatus 1 operating at a driving frequency of A Hz, one frame section 1F may include one first scan period AS and one second scan period SS. As illustrated in FIG. 4B, in the display apparatus 1 operating at a driving frequency of B Hz, which is lower than A Hz, one frame section 1F may include one first scan period AS and two or more second scan periods SS. The lower the driving frequency is, the longer one frame section 1F may be.

The first scan period AS may be defined as an address scan period in which a data signal is written to the pixel PX, and the pixel PX emits light at a luminance corresponding to the written data signal. The operation of writing the data signal DATA to the pixel PX from the data line DL may also be referred to as a data-programming operation. The second scan period SS may be defined as a self-scan period in which the data signal DATA is not written to the pixel PX. During the second scan period SS, the data signal written during the first scan period AS may be maintained, and the pixel PX may emit light at a luminance corresponding to the data signal DATA written during the first scan period AS. The length of the second scan period SS may be identical to the length of the first scan period AS.

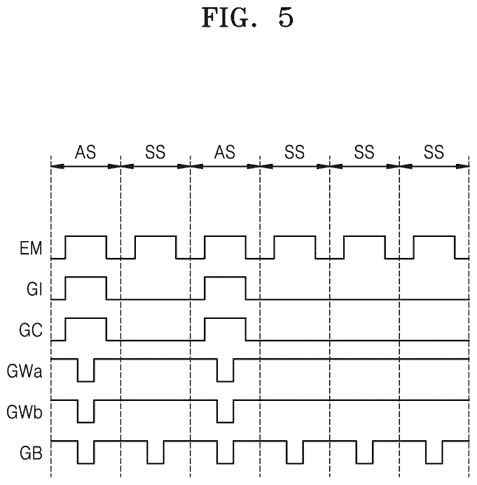

FIG. 5 is a diagram illustrating signals provided to a pixel.

In one or more embodiments, during the first scan period AS and the second scan period SS, the gate-driving circuit 130a may provide the first to fifth gate signals GW (e.g., GWa and GWb), GI, GC, GB, and EM to the first to fifth gate lines GWL, GIL, GCL, GBL, and EML. The start timing and the end timing of the gate-on voltage holding period and the gate-off voltage holding period of the first to fifth gate signals GW, GI, GC, GB, and EM may be identical to or different from each other, and some signals may overlap during a certain period.

During the first scan period AS and the second scan period SS, the power supply circuit 170 may provide the first power voltage ELVDD to the first power supply line PL, may provide a bias voltage VOBS to the bias voltage line VBL, may provide the initialization voltage Vint to the node initialization voltage line VIL, and may provide the initialization voltage Vaint to the initialization voltage line VL.

The first scan period AS may include a period during which a data signal corresponding to an image is written. The first scan period AS may include a period during which the fifth gate signal EM is a gate-off voltage, and a period during which the fifth gate signal EM is a gate-on voltage. The period during which the fifth gate signal EM is a gate-off voltage may be a non-emission section, and the period during which the fifth gate signal EM is a gate-on voltage may be an emission section. The non-emission section may include at least one initialization period and a compensation period. The display apparatus 1 may display an image by varying the driving frequency according to the VRR. For example, during some periods, one frame section 1F may include one first scan period AS and one second scan period SS, and during other periods, one frame section 1F may include one first scan period AS and three second scan periods SS. However, the disclosure is not limited thereto, and in the display apparatus 1, one frame section 1F may include one first scan period AS, or may include one first scan period AS and two or more second scan periods SS.

During some periods of the first scan period AS, the fifth gate signal EM of gate-off voltage (first level voltage) may be supplied to the fifth gate line EML. In the non-emission section in which the fifth gate signal EM of gate-off voltage (first level voltage) is supplied, the 1-1 gate signal GWa, the 1-2 gate signal GWb, and the fourth gate signal GB, each of a gate-on voltage (second level voltage), may respectively be supplied to the 1-1 gate line GWLa, to the 1-2 gate line GWLb, and to the fourth gate line GBL, and the second gate signal GI and the third gate signal GC, each of a gate-on voltage (first level voltage), may respectively be supplied to the second gate line GIL and to the third gate line GCL.

The 2-1 transistor T2-1 may be turned on by the 1-1 gate signal GWa. The 2-2 transistor T2-2 may be turned on by the 1-2 gate signal GWb. When the 2-1 transistor T2-1 and the 2-2 transistor T2-2 are concurrently or substantially simultaneously turned on, the second transistor T2 may transmit the data signal DATA received through the data line DL to the first node N1. Accordingly, the data signal DATA may be supplied to the first terminal of the first transistor T1. The seventh transistor T7 and the eighth transistor T8 may be turned on by the fourth gate signal GB. The pixel electrode of the organic light-emitting diode OLED may be initialized to the initialization voltage Vaint by the turned-on seventh transistor T7, and the bias voltage VOBS may be supplied to the first node N1 by the eighth transistor T8. The fourth transistor T4 may be turned on by the second gate signal GI. The gate of the first transistor T1 may be initialized to the initialization voltage Vint by the turned-on fourth transistor T4. The third transistor T3 may be turned on by the third gate signal GC. By the turned-on third transistor T3, a difference VOBS-Vth between a threshold voltage Vth of the first transistor T1 and the bias voltage VOBS may be supplied to the gate of the first transistor T1, which is in a diode-connected state. A voltage corresponding to the threshold voltage Vth of the first transistor T1 may be charged into the first capacitor Cst. That is, the pixel PX may compensate for the threshold voltage of the first transistor T1 by the bias voltage VOBS of a constant voltage.

During other periods of the first scan period AS, the fifth gate signal EM of gate-on voltage (second level voltage) may be supplied to the fifth gate line EML. In the emission section in which the fifth gate signal EM of gate-on voltage (second level voltage) is supplied, the 1-1 gate signal GWa, the 1-2 gate signal GWb, and the fourth gate signal GB, each of gate-off voltage (first level voltage), may respectively be supplied to the 1-1 gate line GWLa, to the 1-2 gate line GWLb, and to the fourth gate line GBL, and the second gate signal GI and the third gate signal GC, each of gate-off voltage (second level voltage), may respectively be supplied to the second gate line GIL and to the third gate line GCL.

The fifth transistor T5 and the sixth transistor T6 may be turned on by the fifth gate signal EM. A current path from the first power supply line PL to the organic light-emitting diode OLED may be formed by the turned-on fifth transistor T5 and sixth transistor T6. The first transistor T1 may output a driving voltage corresponding to a stored data voltage to the first capacitor Cst, and the organic light-emitting diode OLED may emit light at a luminance corresponding to a driving current irrelevant to the threshold voltage Vth of the first transistor T1.

During some periods of the second scan period SS, the fifth gate signal EM having a gate-off voltage (a first level voltage) may be supplied to the fifth gate line EML. In some sections of the non-emission section in which the fifth gate signal EM of gate-off voltage (first level voltage) is supplied, the fourth gate signal GB of gate-on voltage (second level voltage) may be supplied to the fourth gate line GBL. During other periods of the second scan period SS, the fifth gate signal EM of gate-on voltage (second level voltage) may be supplied to the fifth gate line EML. During the second scan period SS, the 1-1 gate signal GWa and the 1-2 gate signal GWb, each of gate-off voltage (first level voltage), may respectively be supplied to the 1-1 gate line GWLa and the 1-2 gate line GWLb, and the second gate signal GI and the third gate signal GC, each of gate-off voltage (second level voltage), may respectively be supplied to the second gate line GIL and to the third gate line GCL. To maintain the luminance of the image output in the first scan period AS, the second scan period SS may include, in the non-emission section, a period in which the bias voltage VOBS is supplied to the first terminal of the first transistor T1.

A period in which the fourth gate signal GB is supplied may be a biasing period in which the voltage-current characteristics of the first transistor T1 are compensated. The seventh transistor T7 and the eighth transistor T8 may be turned on by the fourth gate signal GB.

By the turned-on seventh transistor T7, the pixel electrode of the organic light-emitting diode OLED may be initialized to the initialization voltage Vaint, and by the turned-on eighth transistor T8, the bias voltage VOBS may be supplied to the first terminal of the first transistor T1 to control the gate-source voltage of the first transistor T1. Then, the change of the voltage-current characteristics of the first transistor T1, which may be due to the stress applied to the first transistor T1 during the first scan period AS, may be compensated. Accordingly, during the subsequent second scan period SS, the pixel PX may maintain the luminance of the image output in the first scan period AS.

In this regard, the provision (application) of the signal may mean provision of the gate-on voltage of the signal. The non-provision (application) of the signal may mean provision of the gate-off voltage.

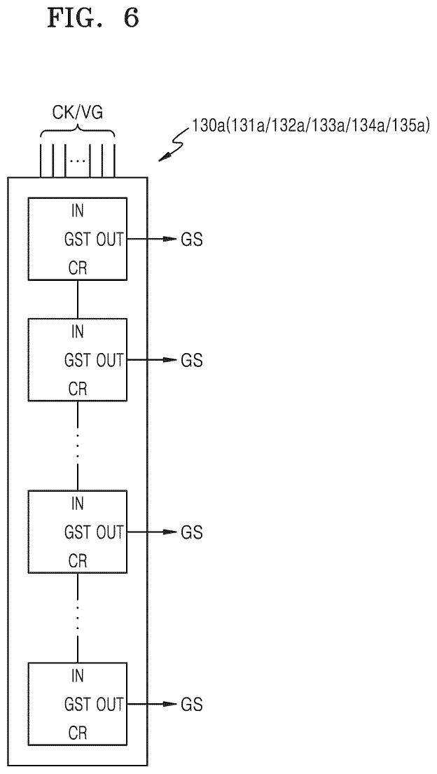

FIG. 6 is a diagram schematically illustrating a gate-driving circuit according to one or more embodiments.

Referring to FIG. 6, the gate-driving circuit 130a may include the first gate-driving circuit 131a, the second gate-driving circuit 132a, the third gate-driving circuit 133a, the fourth gate-driving circuit 134a, and the fifth gate-driving circuit 135a. However, the disclosure is not limited thereto, and a gate-driving circuit 13 may include three or four gate-driving circuits. Some gate-driving circuits may be integrated. Each of the gate-driving circuits may include stages GST arranged in the y direction (column direction).

The stages GST may be connected to each other in the form of a shift register. For example, gate signals GS may be generated by sequentially transmitting a turn-on level pulse of a start signal supplied to a first stage GST to a next stage GST. The stages GST may generate the gate signals GS based on a start signal or an output signal of a previous stage GST (for example, a gate signal GS generated at the previous stage).

Each stage GST may receive at least one clock signal CK and at least one voltage signal VG, and may generate at least one gate signal GS. The stage GST may receive at least one clock signal CK from at least one clock line, and may receive at least one voltage signal VG from at least one voltage line. The stage GST may output at least one gate signal GS to at least one gate line connected thereto.

Each stage GST may output at least one gate signal GS to at least one gate line connected thereto. For example, the first gate-driving circuit 131a may output the first gate signal GW to the first gate line GWL. Each stage GST of the second gate-driving circuit 132a may output the second gate signal GI to the second gate line GIL. Each stage GST of the third gate-driving circuit 133a may output the third gate signal GC to the third gate line GCL. Each stage GST of the fourth gate-driving circuit 134a may output the fourth gate signal GB to the fourth gate line GBL. Each stage GST of the fifth gate-driving circuit 135a may output the fifth gate signal EM to the fifth gate line EML.

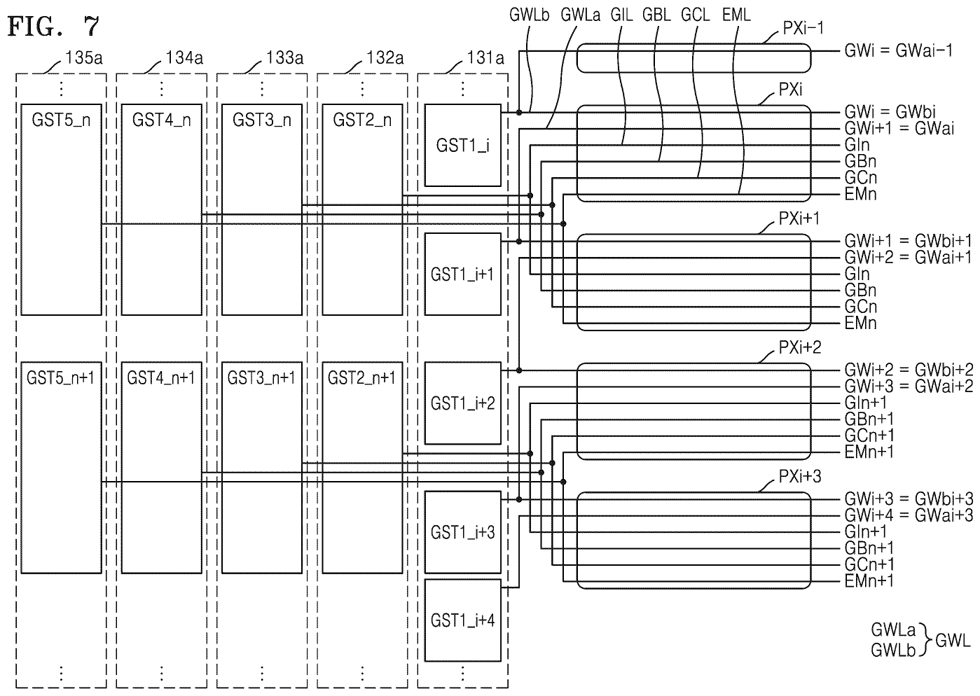

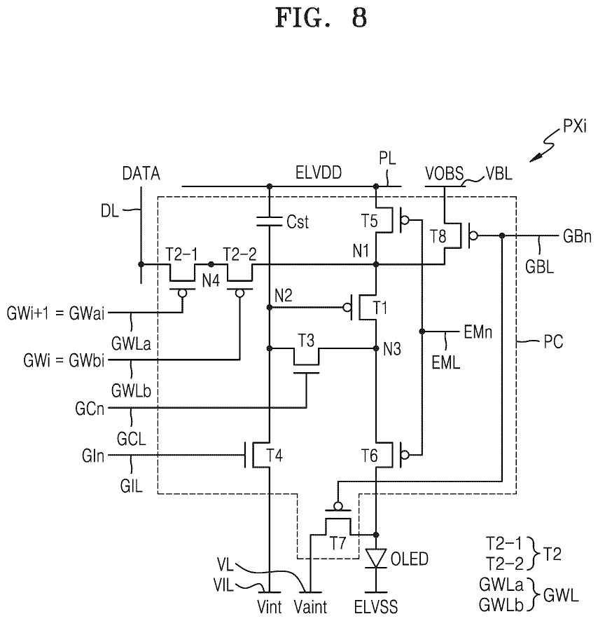

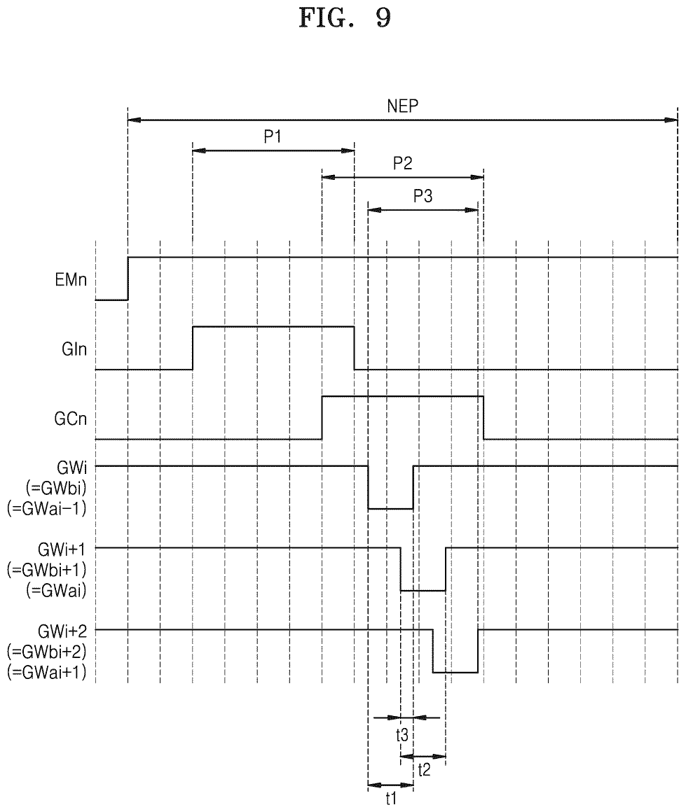

FIG. 7 is a diagram schematically illustrating some stages of a gate-driving circuit and gate lines connected to a pixel according to one or more embodiments. FIG. 8 is a diagram illustrating a pixel PXi arranged in an ith row in a display according to one or more embodiments. FIG. 9 is a diagram illustrating gate signals output by a gate-driving circuit according to one or more embodiments. In FIGS. 2 to 6 and 7 to 9, like reference numerals denote like components, periods, and signals, and any redundant description may be omitted.

Referring to FIG. 7, the gate-driving circuit 130a of the display apparatus according to one or more embodiments may include the first gate-driving circuit 131a, the second gate-driving circuit 132a, the third gate-driving circuit 133a, the fourth gate-driving circuit 134a, and the fifth gate-driving circuit 135a. The first to fifth gate-driving circuits 131a, 132a, 133a, 134a, and 135a may be arranged in the x direction (row direction).

The first gate-driving circuit 131a may include first stages ( . . . , GST1_i, GST1_i+1, GST1_i+2, GST1_i+3, GST1_i+4, . . . ) connected in a subordinate manner. The first stages ( . . . , GST1_i, GST1_i+1, GST1_i+2, GST1_i+3, GST1_i+4, . . . ) may respectively correspond to the rows of the display 110 (FIG. 2).

An ith first stage GST1_i arranged corresponding to an ith row of the first gate-driving circuit 131a may output an ith first gate signal GWi to an i−1th 1-1 gate line GWLa electrically connected to an i−1th pixel PXi−1. The ith first gate signal GWi may be an i−1th 1-1 gate signal GWai−1. In addition, the ith first stage GST1_i may output the ith first gate signal GWi to an ith 1-2 gate line GWLb electrically connected to the ith pixel PXi. The ith first gate signal GWi may be an ith 1-2 gate signal GWbi.

An i+1th first stage GST1_i+1 arranged corresponding to an i+1th row of the first gate-driving circuit 131a may output an i+1th first gate signal GWi+1 to the ith 1-1 gate line GWLa electrically connected to the ith pixel PXi. The i+1th first gate signal GWi+1 may be an ith 1-1 gate signal GWai. In addition, the i+1th first stage GST1_i+1 may output the i+1th first gate signal GWi+1 to an i+1th 1-2 gate line GWLb electrically connected to an i+1th pixel PXi+1. The i+1th first gate signal GWi+1 may be an i+1th 1-2 gate signal GWbi+1.

An i+2th first stage GST1_i+2 arranged corresponding to an i+2th row of the first gate-driving circuit 131a may output an i+2th first gate signal GWi+2 to the i+1th 1-1 gate line GWLa electrically connected to the i+1th pixel PXi+1. The i+2th first gate signal GWi+2 may be an i+1th 1-1 gate signal GWai+1. In addition, the i+2th first stage GST1_i+2 may output the i+2th first gate signal GWi+2 to an i+2th 1-2 gate line GWLb electrically connected to an i+2th pixel PXi+2. The i+2th first gate signal GWi+2 may be an i+2th 1-2 gate signal GWbi+2.

An i+3th first stage GST1_i+3 arranged corresponding to an i+3th row of the first gate-driving circuit 131a may output an i+3th first gate signal GWi+3 to the i+2th 1-1 gate line GWLa electrically connected to the i+2th pixel PXi+2. The i+3th first gate signal GWi+3 may be an i+2th 1-1 gate signal GWai+2. In addition, the i+3th first stage GST1_i+3 may output the i+3th first gate signal GWi+3 to an i+3th 1-2 gate line GWLb electrically connected to an i+3th pixel PXi+3. The i+3th first gate signal GWi+3 may be an i+3th 1-2 gate signal GWbi+3.

An i+4th first stage GST1_i+4 arranged corresponding to an i+4th row of the first gate-driving circuit 131a may output an i+4th first gate signal GWi+4 to the i+3th 1-1 gate line GWLa electrically connected to the i+3th pixel PXi+3. The i+4th first gate signal GWi+4 may be an i+3th 1-1 gate signal GWai+3.

The i−1th pixel PXi−1 to the i+3th pixel PXi+3 illustrated in FIG. 7 are pixels arranged in the same column and may have substantially the same pixel structure.

The second gate-driving circuit 132a may include second stages ( . . . , GST2_n, GST2_n+1, . . . ), and the second stages ( . . . , GST2_n, GST2_n+1, . . . ) may correspond to two or more rows. For example, the second stages ( . . . , GST2_n, GST2_n+1, . . . ) may correspond to two rows of the display 110.

An nth second stage GST2_n of the second gate-driving circuit 132a may output an nth second gate signal GIn concurrently or substantially simultaneously to the ith second gate line GIL electrically connected to the ith pixel PXi and the i+1 second gate line GIL electrically connected to the i+1th pixel PXi+1.

An n+1th second stage GST2_n+1 of the second gate-driving circuit 132a may output an n+1th second gate signal Gin+1 concurrently or substantially simultaneously to the i+2th second gate line GIL electrically connected to the i+2th pixel PXi+2 and to the i+3th second gate line GIL electrically connected to the i+3th pixel PXi+3.

The third gate-driving circuit 133a may include third stages ( . . . , GST3_n, GST3_n+1, . . . ), and the third stages ( . . . , GST3_n, GST3_n+1, . . . ) may correspond to two or more rows. For example, the third stages ( . . . , GST3_n, GST3_n+1, . . . ) may correspond to two rows of the display 110.

An nth third stage GST3_n of the third gate-driving circuit 133a may output an nth third gate signal GCn concurrently or substantially simultaneously to the ith third gate line GCL electrically connected to the ith pixel PXi and to the i+1 third gate line GCL electrically connected to the i+1th pixel PXi+1.

An n+1th third stage GST3_n+1 of the third gate-driving circuit 133a may output an n+1th third gate signal GCn+1 concurrently or substantially simultaneously to the i+2th third gate line GCL electrically connected to the i+2th pixel PXi+2 and to the i+3th third gate line GCL electrically connected to the i+3th pixel PXi+3.

The fourth gate-driving circuit 134a may include fourth stages ( . . . , GST4_n, GST4_n+1, . . . ), and the fourth stages ( . . . , GST4_n, GST4_n+1, . . . ) may correspond to two or more rows. For example, the fourth stages ( . . . , GST4_n, GST4_n+1, . . . ) may correspond to two rows of the display 110.

An nth fourth stage GST4_n of the fourth gate-driving circuit 134a may output an nth fourth gate signal GBn concurrently or substantially simultaneously to the ith fourth gate line GBL electrically connected to the ith pixel PXi and to the i+1 fourth gate line GBL electrically connected to the i+1th pixel PXi+1.

An n+1th fourth stage GST4_n+1 of the fourth gate-driving circuit 134a may output an n+1th fourth gate signal GBn+1 concurrently or substantially simultaneously to the i+2th fourth gate line GBL electrically connected to the i+2th pixel PXi+2 and to the i+3th fourth gate line GBL electrically connected to the i+3th pixel PXi+3.

The fifth gate-driving circuit 135a may include fifth stages ( . . . , GST5_n, GST5_n+1, . . . ), and the fifth stages ( . . . , GST5_n, GST5_n+1, . . . ) may correspond to two or more rows. For example, the fifth stages ( . . . , GST5_n, GST5_n+1, . . . ) may correspond to two rows of the display 110.

An nth fifth stage GST5_n of the fifth gate-driving circuit 135a may output an nth fifth gate signal EMn concurrently or substantially simultaneously to the ith fifth gate line EML electrically connected to the ith pixel PXi and to the i+1 fifth gate line EML electrically connected to the i+1th pixel PXi+1.

An n+1th fifth stage GST5_n+1 of the fifth gate-driving circuit 135a may output an n+1th fifth gate signal EMn+1 concurrently or substantially simultaneously to the i+2th fifth gate line EML electrically connected to the i+2th pixel PXi+2 and to the i+3th fifth gate line EML electrically connected to the i+3th pixel PXi+3.

Referring to FIG. 8, the pixel PXi arrange in the ith row of the display 110 may receive the ith first gate signal GWi from the ith first stage GST1_i of the first gate-driving circuit 131a through the ith 1-2 gate line GWLb, and may receive the i+1th first gate signal GWi+1 from the i+1th first stage GST1_i+1 of the first gate-driving circuit 131a through the ith 1-1 gate line GWLa.

The pixel PXi may include the 2-2 transistor T2-2 and the 2-1 transistor T2-1 serially connected to the second transistor T2. The 2-1 transistor T2-1 may receive the i+1th first gate signal GWi+1 through the ith 1-1 gate line GWLa, and the 2-2 transistor T2-2 may receive the ith first gate signal GWi through the ith 1-2 gate line GWLb. That is, the ith first gate signal GWi may be the ith 1-2 gate signal GWbi, which turns on the 2-2 transistor T2-2. The i+1th first gate signal GWi+1 may be the ith 1-1 gate signal GWai, which turns on the 2-1 transistor T2-1.

FIG. 9 is a diagram illustrating some gate signals during the first scan period AS. Referring to FIG. 9, a non-emission period NEP may include a first period P1, a second period P2, and a third period P3. The first period P1 may be a period in which the second node N2 connected to the gate of the first transistor T1 is initialized. During the first period P1, an nth second gate signal GIn of the gate-on voltage (the first level voltage) may be supplied to the ith second gate line GIL. The second period P2 may be a period in which the threshold voltage of the first transistor T1 is compensated. During the second period P2, the nth third gate signal GCn of the gate-on voltage (the first level voltage) may be supplied to the ith third gate line GCL. The first period P1 and the second period P2 may overlap. The third period P3 may be a writing period in which the data signal is supplied to the pixel. During the third period P3, the ith first gate signal GWi of the gate-on voltage (the second level voltage) may be supplied to the ith 1-2 gate line GWLb, and the i+1th first gate signal GWi+1 of the gate-on voltage (the second level voltage) may be supplied to the ith 1-1 gate line GWLa. During at least some periods of a period t1 in which the ith first gate signal GWi of the gate-on voltage (the second level voltage) is supplied to the ith 1-2 gate line GWLb, the i+1th first gate signal GWi+1 of the gate-on voltage (the second level voltage) may be supplied to the ith 1-1 gate line GWLa. After the 2-2 transistor T2-2 is turned on during the period t1, the 2-1 transistor T2-1 may be turned on during a period t2. During a period t3, which is an overlapped period between the period t1 and the period t2, the second transistor T2 may be turned on. The turned-on second transistor T2 may transmit the data signal DATA from the data line DL to the first node N1.

During when the nth third gate signal GCn is applied in the second period P2, the ith first gate signal GWi, the i+1th first gate signal GWi+1, and the i+2th first gate signal GWi+2 may be applied.

When the display apparatus 1 is driven at a high driving frequency, the time for writing the data signal to the pixel may be reduced. As described above, the second transistor T2 may transmit the data signal DATA to the first node N1 according to the first gate signal GW. In this regard, when the time in which the first gate signal GW is maintained at the gate-on voltage is reduced in the second transistor T2, due to the delay caused by conversion of the gate-off/on voltage into the gate-on/off voltage, the data signal DATA may not be sufficiently written, and accordingly, the driving margin of the display apparatus 1 may be insufficient.

However, according to one or more embodiments, the second transistor T2 of the pixel PX included in the display apparatus 1 may include the 2-1 transistor T2-1 and the 2-2 transistor T2-2, which are serially connected to each other. The gates of the 2-1 transistor T2-1 and the 2-2 transistor T2-2 may respectively be connected to the 1-1 gate line GWLa and to the 1-2 gate line GWLb. The 2-2 transistor T2-2 and the 2-1 transistor T2-1 may be sequentially turned on by the first gate signal GW supplied through the 1-2 gate line GWLb and the 1-1 gate line GWLa. The 1-2 gate signal GWb turning on the 2-2 transistor T2-2 and the 1-1 gate signal GWa turning on the 2-1 transistor T2-1 may each be the first gate signal GW, which is supplied sequentially. For example, when the 1-2 gate signal GWb is a first first gate signal GW, the 1-1 gate signal GWa may be a second first gate signal GW. When both the 2-2 transistor T2-2 and the 2-1 transistor T2-1 are turned on, the second transistor T2 may be turned on. According to one or more embodiments, the time, in which each of the 1-2 gate signal GWb turning on the 2-2 transistor T2-2 and the 1-1 gate signal GWa turning on the 2-1 transistor T2-1 are maintained at the gate-on voltage, may be sufficiently secured. By using the period in which the 2-1 transistor T2-1 and the 2-2 transistor T2-2 are concurrently or substantially simultaneously turned on as a valid data writing period, the data signal DATA may be sufficiently transmitted to the first node N1.

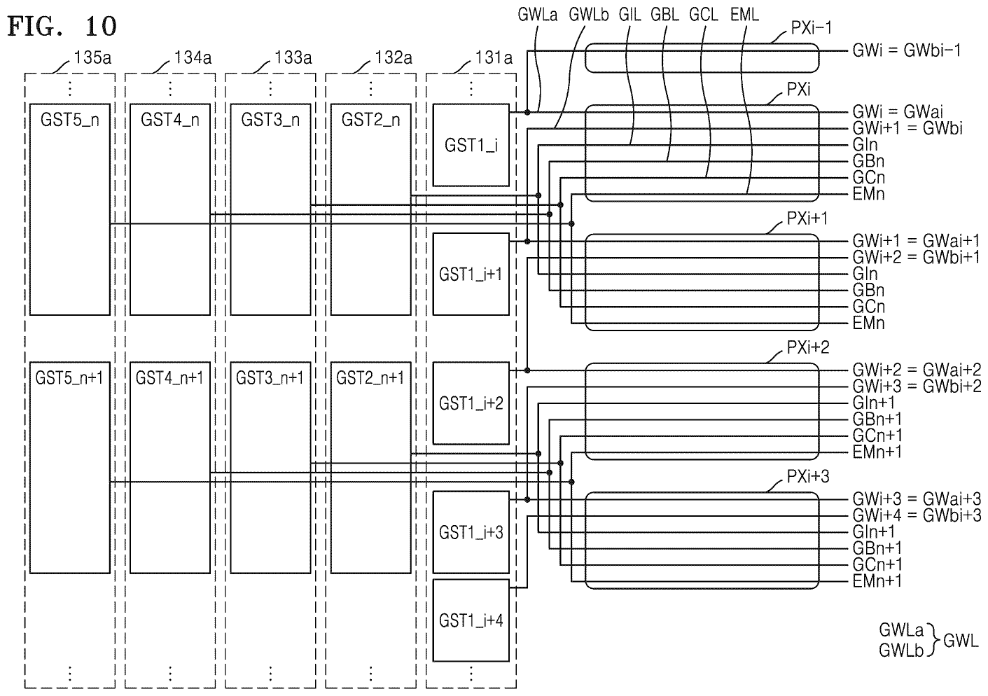

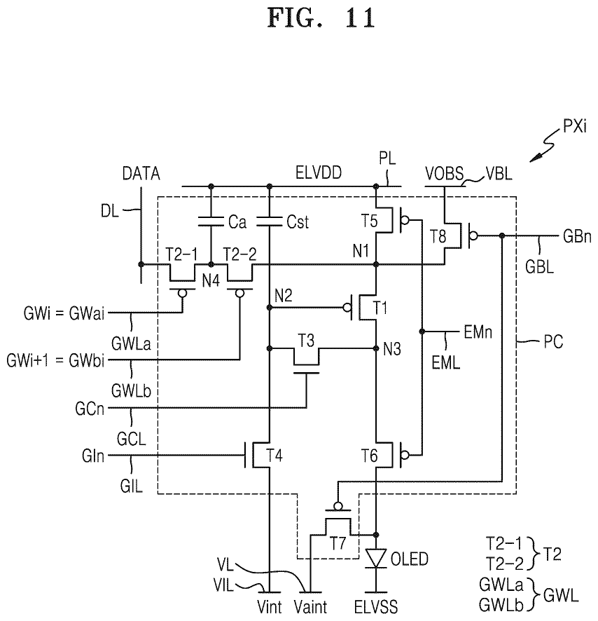

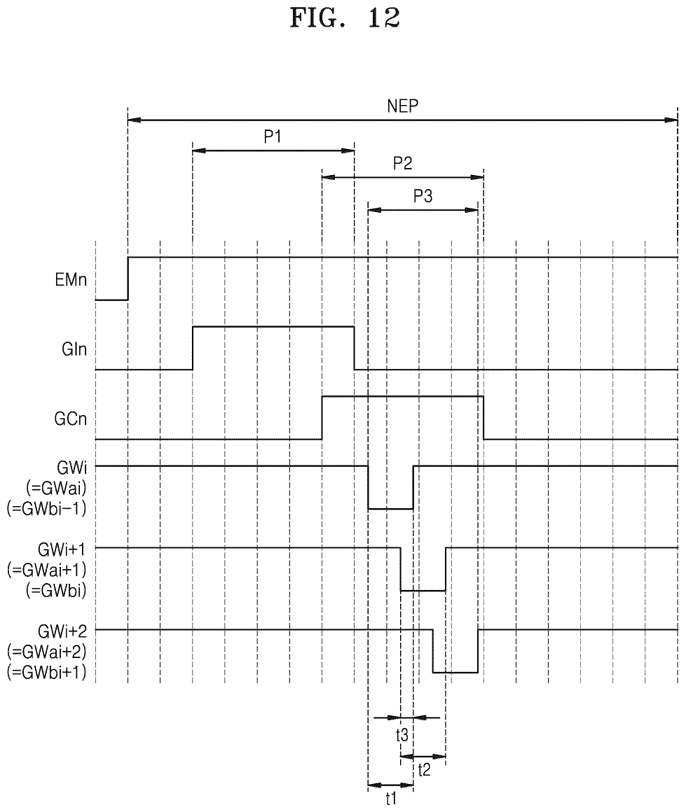

FIG. 10 is a diagram schematically illustrating some stages of a gate-driving circuit and gate lines connected to a pixel according to one or more embodiments. FIG. 11 is a diagram illustrating the pixel PXi arranged in the ith row in the display according to one or more embodiments. FIG. 12 is a diagram illustrating gate signals output by a gate-driving circuit according to one or more embodiments. FIGS. 10 to 12 are modification examples of FIGS. 7 to 9, and accordingly, embodiments are now described focusing on differences, and any redundant description will be omitted.

Referring to FIG. 10, the gate-driving circuit 130a of the display apparatus according to one or more embodiments may include the first gate-driving circuit 131a, the second gate-driving circuit 132a, the third gate-driving circuit 133a, the fourth gate-driving circuit 134a, and the fifth gate-driving circuit 135a. The one or more embodiments corresponding to FIG. 10 is different from the one or more embodiments corresponding to FIG. 7 in terms of the first gate-driving circuit 131a.

The first gate-driving circuit 131a may include first stages ( . . . , GST1_i, GST1_i+1, GST1_i+2, GST1_i+3, GST1_i+4, . . . ) connected in a subordinate manner. The first stages ( . . . , GST1_i, GST1_i+1, GST1_i+2, GST1_i+3, GST1_i+4, . . . ) may respectively correspond to the rows of the display 110 (FIG. 2).

The ith first stage GST1_i arranged corresponding to the ith row of the first gate-driving circuit 131a may output the ith first gate signal GWi to an i−1th 1-2 gate line GWLb electrically connected to the i−1th pixel PXi−1. The ith first gate signal GWi may be an i−1th 1-2 gate signal GWbi−1. In addition, the ith first stage GST1_i may output the ith first gate signal GWi to the ith 1-1 gate line GWLa electrically connected to the ith pixel PXi. The ith first gate signal GWi may be the ith 1-1 gate signal GWai.

The i+1th first stage GST1_i+1 arranged corresponding to the i+1th row of the first gate-driving circuit 131a may output the i+1th first gate signal GWi+1 to the ith 1-2 gate line GWLb electrically connected to the ith pixel PXi. The i+1th first gate signal GWi+1 may be the ith 1-2 gate signal GWbi. In addition, the i+1th first stage GST1_i+1 may output the i+1th first gate signal GWi+1 to the i+1th 1-1 gate line GWLa electrically connected to an i+1th pixel PXi+1. The i+1th first gate signal GWi+1 may be the i+1th 1-1 gate signal GWai+1.

The i+2th first stage GST1_i+2 arranged corresponding to the i+2th row of the first gate-driving circuit 131a may output the i+2th first gate signal GWi+2 to the i+1th 1-2 gate line GWLb electrically connected to the i+1th pixel PXi+1. The i+2th first gate signal GWi+2 may be the i+1th 1-2 gate signal GWbi+1. In addition, the i+2th first stage GST1_i+2 may output the i+2th first gate signal GWi+2 to an i+2th 1-1 gate line GWLa electrically connected to the i+2th pixel PXi+2. The i+2th first gate signal GWi+2 may be the i+2th 1-1 gate signal GWai+2.

The i+3th first stage GST1_i+3 arranged corresponding to the i+3th row of the first gate-driving circuit 131a may output the i+3th first gate signal GWi+3 to the i+2th 1-2 gate line GWLb electrically connected to the i+2th pixel PXi+2. The i+3th first gate signal GWi+3 may be the i+2th 1-2 gate signal GWbi+2. In addition, the i+3th first stage GST1_i+3 may output the i+3th first gate signal GWi+3 to the i+3th 1-1 gate line GWLa electrically connected to the i+3th pixel PXi+3. The i+3th first gate signal GWi+3 may be the i+3th 1-1 gate signal GWai+3.

The i+4th first stage GST1_i+4 arranged corresponding to the i+4th row of the first gate-driving circuit 131a may output the i+4th first gate signal GWi+4 to the i+3th 1-2 gate line GWLb electrically connected to the i+3th pixel PXi+3. The i+4th first gate signal GWi+4 may be the i+3th 1-2 gate signal GWbi+3.

Referring to FIGS. 10 to 12, the pixel PXi arrange in the ith row of the display 110 may receive the ith first gate signal GWi from the ith first stage GST1_i of the first gate-driving circuit 131a through the ith 1-1 gate line GWLa, and may receive the i+1th first gate signal GWi+1 from the i+1th first stage GST1_i+1 of the first gate-driving circuit 131a through the ith 1-2 gate line GWLb.

The pixel PXi may include the 2-2 transistor T2-2 and the 2-1 transistor T2-1 serially connected to the second transistor T2. The 2-1 transistor T2-1 may receive the ith first gate signal GWi through the ith 1-1 gate line GWLa, and the 2-2 transistor T2-2 may receive the i+1th first gate signal GWi+1 through the ith 1-2 gate line GWLb. That is, the ith first gate signal GWi may be the ith 1-1 gate signal GWai, which turns on the 2-1 transistor T2-1. The i+1th first gate signal GWi+1 may be the ith 1-2 gate signal GWbi, which turns on the 2-2 transistor T2-2.

Referring to FIG. 11, the pixel circuit PC may include the first to eighth transistors T1 to T8, the first capacitor Cst, and a second capacitor Ca. The second capacitor Ca may include a first electrode connected to the fourth node N4 between the 2-1 transistor T2-1 and the 2-2 transistor T2-2 of the second transistor T2, and a second electrode connected to the first power supply line PL. When the 2-1 transistor T2-1 is turned on, and then the 2-2 transistor T2-2 is turned on, the second capacitor Ca may reduce or prevent coupling of the fourth node N4.

Referring to FIG. 12, during the third period P3 of the non-emission period NEP, the ith first gate signal GWi of the gate-on voltage (the second level voltage) may be supplied to the ith 1-1 gate line GWLa. The i+1th first gate signal GWi+1 of the gate-on voltage (the second level voltage) may be supplied to the ith 1-2 gate line GWLb. During at least some periods of the period t1 in which the ith first gate signal GWi of the gate-on voltage (the second level voltage) is supplied to the ith 1-1 gate line GWLa, the i+1th first gate signal GWi+1 of the gate-on voltage (the second level voltage) may be supplied to the ith 1-2 gate line GWLb. After the 2-1 transistor T2-1 is turned on during the period t1, the 2-2 transistor T2-2 may be turned on during the period t2. During a period t3, which is an overlapped period between the period t1 and the period t2, the second transistor T2 may be turned on. The turned-on second transistor T2 may transmit the data signal DATA from the data line DL to the first node N1.

According to one or more embodiments, the second transistor T2 of the pixel PX included in the display apparatus 1 may include the 2-1 transistor T2-1 and the 2-2 transistor T2-2, which are serially connected to each other. The gates of the 2-1 transistor T2-1 and the 2-2 transistor T2-2 may respectively be connected to the 1-1 gate line GWLa and the 1-2 gate line GWLb. The 2-1 transistor T2-1 and the 2-2 transistor T2-2 may be sequentially turned on by the first gate signal GW supplied through the 1-1 gate line GWLa and the 1-2 gate line GWLb. The 1-1 gate signal GWa turning on the 2-1 transistor T2-1 and the 1-2 gate signal GWb turning on the 2-2 transistor T2-2 may each be the first gate signal GW, which may be supplied sequentially. For example, when the 1-1 gate signal GWa is a first first gate signal GW, the 1-2 gate signal GWb may be a second first gate signal GW. When both the 2-1 transistor T2-1 and the 2-2 transistor T2-2 are turned on, the second transistor T2 may be turned on. According to one or more embodiments, the time, in which each of the 1-1 gate signal GWa turning on the 2-1 transistor T2-1 and the 1-2 gate signal GWb turning on the 2-2 transistor T2-2 are maintained at the gate-on voltage, may be sufficiently secured. By using the period in which the 2-1 transistor T2-1 and the 2-2 transistor T2-2 are concurrently or substantially simultaneously turned on as a valid data writing period, the data signal DATA may be sufficiently transmitted to the first node N1.

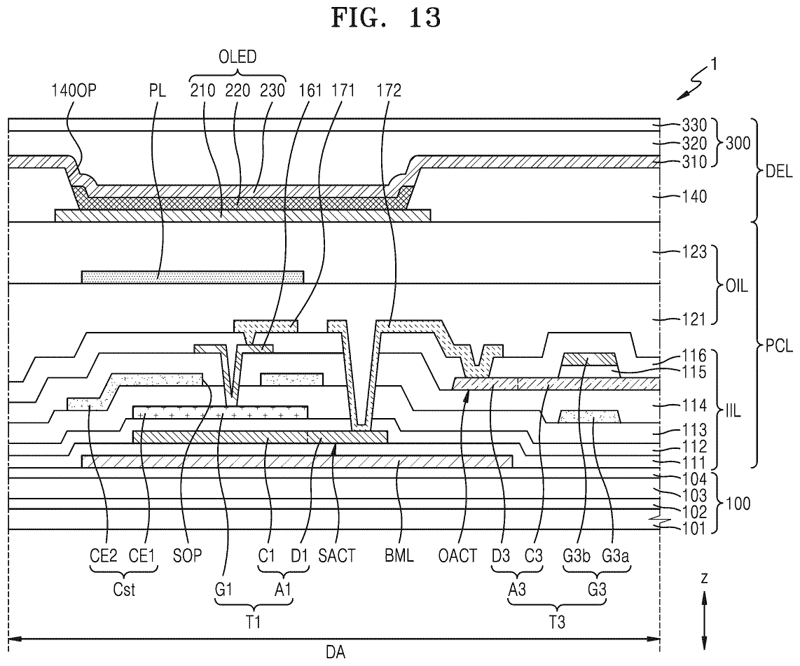

FIG. 13 is a cross-sectional view of a part of a display apparatus according to one or more embodiments.

Referring to FIG. 13, the display area DA may include pixel areas in which pixel circuits PC of the pixels PX of the display 110 are arranged. The pixel areas may be arranged in the x direction (row direction) and the y direction (column direction). In one pixel area, the display apparatus 1 may include a substrate 100, a pixel circuit layer PCL, and a light-emitting diode layer DEL.

The pixel circuit layer PCL may define pixel circuits. The pixel circuit layer PCL may include components of transistors and capacitors, and may include insulating layers arranged on/under the components. In this regard, FIG. 13 illustrates the first transistor T1, the third transistor T3, and the first capacitor Cst from among the transistors and capacitors included in the pixel circuit. In addition, the pixel circuit layer PCL may include inorganic insulating layers IIL and organic insulating layers OIL. For example, as illustrated in FIG. 13, the inorganic insulating layers IIL may include a buffer layer 111, a first gate-insulating layer 112, a first interlayer insulating layer 113, a second interlayer insulating layer 114, a second gate-insulating layer 115, and a third interlayer insulating layer 116. The organic insulating layers OIL may include a first organic insulating layer 121 and a second organic insulating layer 123.

The substrate 100 may include a glass material, a ceramic material, a metal material, plastic, or a material having flexible or bendable characteristics. When the substrate 100 is flexible or bendable, the substrate 100 may include a polymer resin, such as polyethersulfone (PES), polyacrylate, polyetherimide (PEI), polyethylene naphthalate (PEN), polyethylene terephthalate (PET), polyphenylene sulfide (PPS), polyarylate, polyimide (PI), polycarbonate (PC), or cellulose acetate propionate.

The substrate 100 may have a single-layer or multi-layer structure of the above material, and for a multi-layer structure, an inorganic layer may be further included. For example, the substrate 100 may include a first organic base layer 101, a first inorganic barrier layer 102, a second organic base layer 103, and a second inorganic barrier layer 104. The first organic base layer 101 and the second organic base layer 103 may each include polymer resin. The first inorganic barrier layer 102 and the second inorganic barrier layer 104 may be a barrier layer reducing or preventing intrusion of external foreign materials and may be a single layer or a multi-layer including an inorganic insulating material such as a silicon nitride and/or a silicon oxide.

A bottom metal layer BML may be arranged on the substrate 100. The bottom metal layer BML may include at least one material selected from among aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu). In one or more embodiments, the bottom metal layer BML may be a single layer of molybdenum or have a double-layer structure in which a molybdenum layer and a titanium layer are stacked or a triple-layer structure in which a titanium layer, an aluminum layer, and a titanium layer are stacked.

The buffer layer 111 may be arranged on the bottom metal layer BML. The buffer layer 111 may be an inorganic insulating layer including an inorganic insulating material such as a silicon nitride and/or a silicon oxide, and may have a single-layer or multi-layer structure including the aforementioned material.

Silicon semiconductor layers of silicon-based transistors may be arranged on the buffer layer 111. In this regard, FIG. 13 illustrates a semiconductor layer A1 of the first transistor T1, which correspond to a part of a silicon semiconductor pattern SACT. The semiconductor layer A1 may include a channel area C1 and impurity areas respectively arranged on both sides of the channel area C1 and doped with impurities, and FIG. 13 illustrates a second area D1, which is one of the impurity areas arranged on one side of the channel area C1.

The first gate-insulating layer 112 may be arranged on the silicon semiconductor pattern SACT. The first gate-insulating layer 112 may be an inorganic insulating layer including an inorganic insulating material, such as a silicon oxide, a silicon nitride, and/or a silicon oxynitride, and may have a single-layer or multi-layer structure including the aforementioned material.

A gate electrode G1 and a first capacitor electrode CE1 may be located on the first gate-insulating layer 112. FIG. 13 illustrates that the gate electrode G1 is integrated with the first capacitor electrode CE1. In other words, the gate electrode G1 may perform the function of the first capacitor electrode CE1, or the first capacitor electrode CE1 may perform the function of the gate electrode G1.

The gate electrode G1 and/or the first capacitor electrode CE1 may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and may have a single-layer or multi-layer structure including the aforementioned material.

The first interlayer insulating layer 113 may be arranged on the gate electrode G1 and/or the first capacitor electrode CE1. The first interlayer insulating layer 113 may be an inorganic insulating layer including an inorganic insulating material, such as a silicon oxide, a silicon nitride, and/or a silicon oxynitride, and may have a single-layer or multi-layer structure including the aforementioned material.

A second capacitor electrode CE2 may be arranged on the first interlayer insulating layer 113. The second capacitor electrode CE2 may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and may have a single-layer or multi-layer structure including the aforementioned material. The second capacitor electrode CE2 may overlap the gate electrode G1 and/or the first capacitor electrode CE1. The second capacitor electrode CE2 may include an opening SOP connecting a connection electrode 161 electrically connected to a first connection electrode 171 to the gate electrode G1. The opening SOP may partially overlap the gate electrode G1. In one or more embodiments, another end of the first connection electrode 171 may be electrically connected to a source area of the third transistor T3.

The second interlayer insulating layer 114 may be arranged on the second capacitor electrode CE2. The second interlayer insulating layer 114 may be an inorganic insulating layer including an inorganic insulating material, such as a silicon oxide, a silicon nitride, and/or a silicon oxynitride, and may have a single-layer or multi-layer structure including the aforementioned material.

Oxide semiconductor layers may be arranged on the second interlayer insulating layer 114. In this regard, FIG. 13 illustrates a semiconductor layer A3 of the third transistor T3, which correspond to a part of an oxide semiconductor pattern OACT. The semiconductor layer A3 may include a channel area C3, and conductive areas respectively arranged on both sides of the channel area C3, and FIG. 13 illustrates a second area D3, which is one of the conductive areas arranged on one side of the channel area C3. A vertical distance between the semiconductor layer A3 and the substrate 100 may be greater than a vertical distance between the semiconductor layer A1 and the substrate 100.

A gate electrode G3 may be arranged under and/or on the third semiconductor layer A3. FIG. 13 illustrates that the gate electrode G3 includes a lower gate electrode G3a arranged under the semiconductor layer A3 and an upper gate electrode G3b arranged on the semiconductor layer A3. In one or more other embodiments, any one of the lower gate electrode G3a or the upper gate electrode G3b may be omitted.

The lower gate electrode G3a may include the same material as the second capacitor electrode CE2, and may be located on the same layer as the second capacitor electrode CE2 (e.g., on the first interlayer insulating layer 113). The upper gate electrode G3b may be arranged on the semiconductor layer A3 with the second gate-insulating layer 115 arranged therebetween. The upper gate electrode G3b may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and may have a single-layer or multi-layer structure including the aforementioned material.

FIG. 13 illustrates that the second gate-insulating layer 115 is arranged between the upper gate electrode G3b and the semiconductor layer A3, although the disclosure is not limited thereto. In one or more other embodiments, the second gate-insulating layer 115 may be formed to entirely cover the substrate 100 along with another insulating layer, for example, the first gate-insulating layer 112. The second gate-insulating layer 115 may be an inorganic insulating layer including an inorganic insulating material, such as a silicon oxide, a silicon nitride, and/or a silicon oxynitride, and may have a single-layer or multi-layer structure including the aforementioned material.

The third interlayer insulating layer 116 may be arranged on the upper gate electrode G3b and the connection electrode 161. The third interlayer insulating layer 116 may be an inorganic insulating layer including an inorganic insulating material, such as a silicon oxide, a silicon nitride, and/or a silicon oxynitride, and may have a single-layer or multi-layer structure including the aforementioned material.

The first connection electrode 171 and the second connection electrode 172 may be arranged on the third interlayer insulating layer 116. The first connection electrode 171 and the second connection electrode 172 may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and may have a single-layer or multi-layer structure including the aforementioned material. For example, the first connection electrode 171 and the second connection electrode 172 may include a triple-layer structure in which a titanium layer, an aluminum layer, and a titanium layer.

The second connection electrode 172 may electrically connect the semiconductor layer A1 to the semiconductor layer A3. The second connection electrode 172 may be connected to a part of the semiconductor layer A1 (for example, D1 of FIG. 13) through a contact hole passing through inorganic insulating layers arranged between the semiconductor layer A1 and the second connection electrode 172 (e.g., the first gate-insulating layer 112, the first interlayer insulating layer 113, the second interlayer insulating layer 114, and the third interlayer insulating layer 116). The second connection electrode 172 may be connected to a part of the semiconductor layer A3 (for example, D3 of FIG. 13) through a contact hole passing through the third interlayer insulating layer 116 arranged between the semiconductor layer A3 and the second connection electrode 172.

The bottom metal layer BML may have a voltage level of constant voltage. The bottom metal layer BML may reduce or prevent congregation of (−) charges at the bottom of the semiconductor layer A1 of the first transistor T1 to reduce, prevent, or minimize the issue of afterimage generation due to (−) charges.

The first organic insulating layer 121 may be formed on the second connection electrode 172 and the first connection electrode 171. The first organic insulating layer 121 may include an organic material, such as acryl, benzocyclobutene (BCB), polyimide, or hexamethyldisiloxane (HMDSO).

The first power supply line PL may be arranged on the first organic insulating layer 121. The second organic insulating layer 123 may be arranged on the first power supply line PL. The first power supply line PL may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), and/or tungsten (W). In one or more embodiments, the first power supply line PL may include a triple-layer structure of a titanium layer, an aluminum layer, and a titanium layer.

The second organic insulating layer 123 may include an organic material, such as benzocyclobutene (BCB), polyimide, or hexamethyldisiloxane (HMDSO).

The light-emitting diode layer DEL may be arranged on the pixel circuit layer PCL. The light-emitting diode layer DEL may include a light-emitting diode. For example, the light-emitting diode layer DEL may include the organic light-emitting diode OLED. The organic light-emitting diode OLED may include a pixel electrode 210, an emission layer 220, and an opposite electrode 230.

The pixel electrode 210 of the organic light-emitting diode OLED may be formed on the second organic insulating layer 123. The emission layer 220 may include a low-molecular weight organic material or a high-molecular weight organic material. At least one layer selected from among a hole injection layer HIL, a hole transport layer HTL, an electron transport layer ETL, and an electron injection layer EIL may be further arranged between the pixel electrode 210 and the opposite electrode 230.

An edge of the pixel electrode 210 may be covered by a bank layer 140, and an inner portion of the pixel electrode 210 may overlap the emission layer 220 through an opening 140OP of the bank layer 140. The pixel electrode 210 may be formed in correspondence with the plurality of organic light-emitting diodes OLED whereas the opposite electrode 230 may be formed separately from the organic light-emitting diodes OLED. In other words, the plurality of organic light-emitting diode OLED may share the opposite electrode 230, and the stacked structure of the pixel electrode 210, the emission layer 220, and a part of the opposite electrode 230 may correspond to the organic light-emitting diode OLED.

An encapsulation layer 300 may be arranged on the organic light-emitting diode OLED. The encapsulation layer 300 may include at least one inorganic encapsulation layer and at least one organic encapsulation layer. FIG. 13 illustrates an example in which the encapsulation layer 300 includes a first inorganic encapsulation layer 310, an organic encapsulation layer 320, and a second inorganic encapsulation layer 330. The first inorganic encapsulation layer 310 and the second inorganic encapsulation layer 330 may include a silicon oxide, a silicon nitride, and/or a silicon oxynitride, and the organic encapsulation layer 320 may include an organic insulating material.

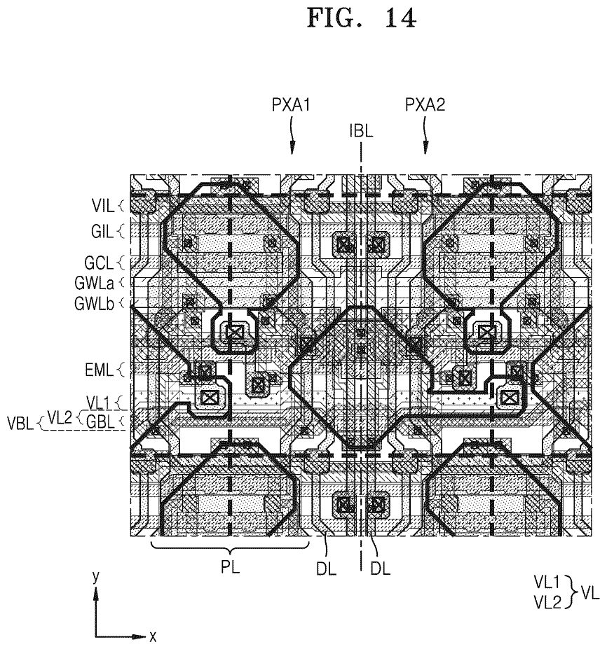

FIG. 14 is an arrangement view schematically illustrating positions of devices arranged in a pixel circuit of a display apparatus according to one or more embodiments. FIG. 14 may correspond to the one or more embodiments of the pixel circuit of FIG. 8.

FIG. 14 illustrates pixel areas that are arranged in the same row and adjacent to each other. For example, FIG. 14 illustrates a pixel circuit of a first pixel area PXA1 and a pixel circuit of a second pixel area PXA2. The pixel circuit of the first pixel area PXA1 and the pixel circuit of the second pixel area PXA2 may be bilaterally symmetrical with respect to a border line IBL between the first pixel area PXA1 and the second pixel area PXA2.

Pixel areas arranged in the same row may share the 1-1 gate line GWLa, the 1-2 gate line GWLb, the second gate line GIL, the third gate line GCL, the fourth gate line GBL, the fifth gate line EML, the bias voltage line VBL, and the node initialization voltage line VIL. In one or more embodiments, the pixel circuits of the pixel areas arranged in the same row in consideration of emission characteristics of each pixel may be connected to different initialization voltage lines VL from each other. For example, a first initialization voltage line VL1 may be connected to a pixel circuit of a red pixel such that the seventh transistor T7 may receive a first initialization voltage from the first initialization voltage line VL1, and a second initialization voltage line VL2 may be connected to a pixel circuit of a green pixel and a blue pixel such that the seventh transistor T7 may receive a second initialization voltage from the second initialization voltage line VL2.

In one or more embodiments, as illustrated further below, the second gate line GIL may include a lower second gate line SGIL and an upper second gate line UGIL. The third gate line GCL may include a lower third gate line SGCL and an upper third gate line UGCL. The fifth gate line EML may include a first lower fifth gate line SEML1, a second lower fifth gate line SEML2, and an upper fifth gate line UEML.

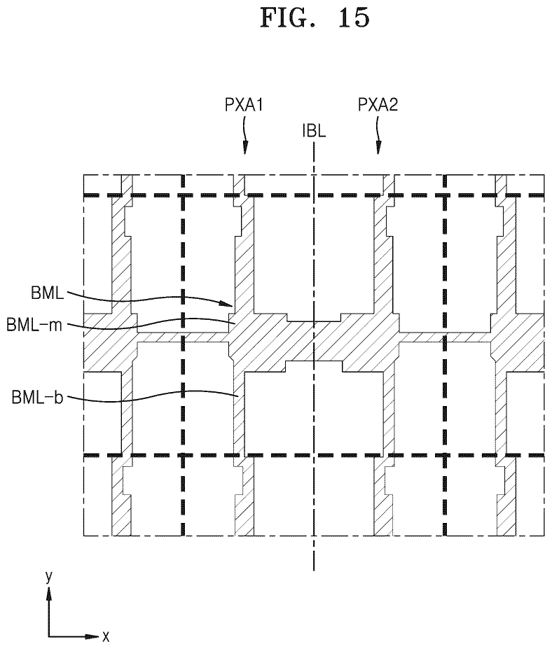

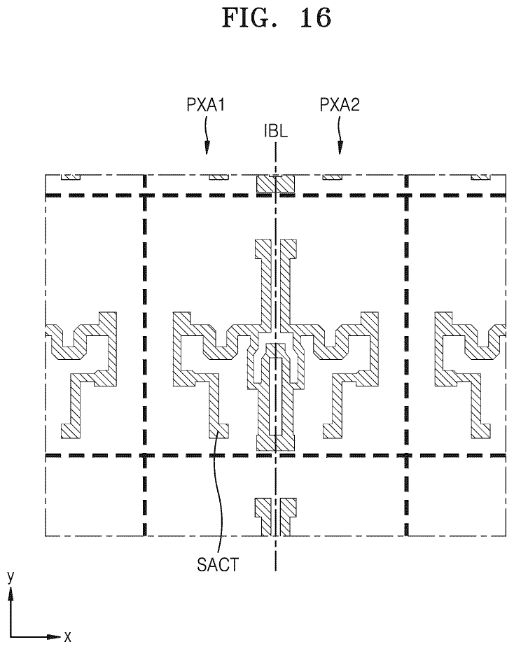

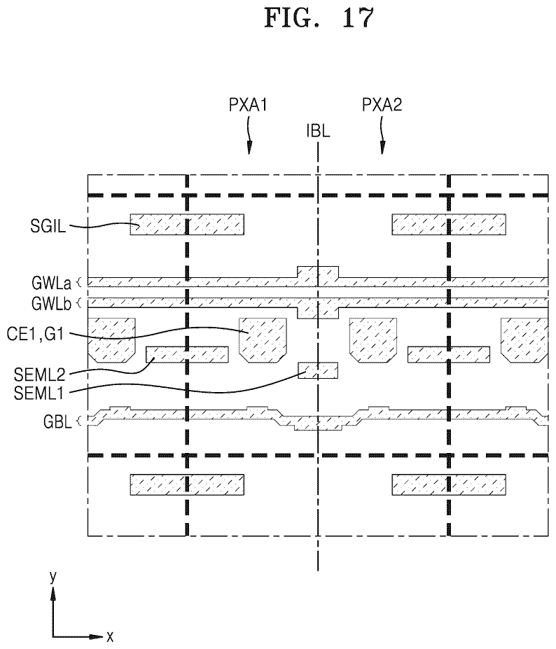

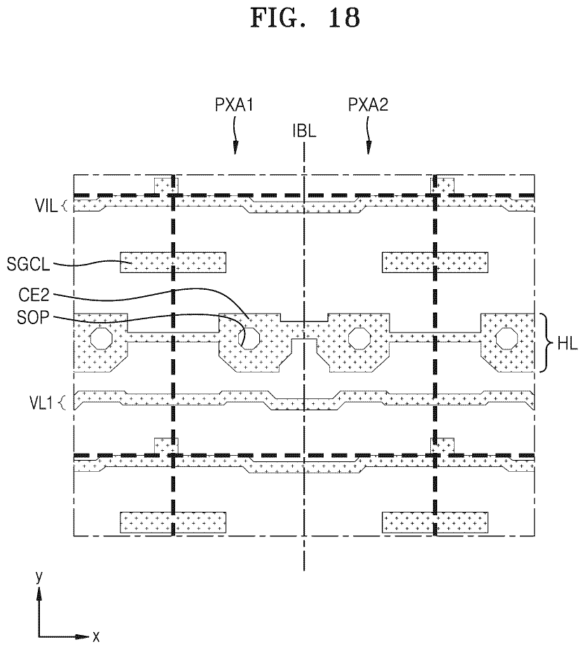

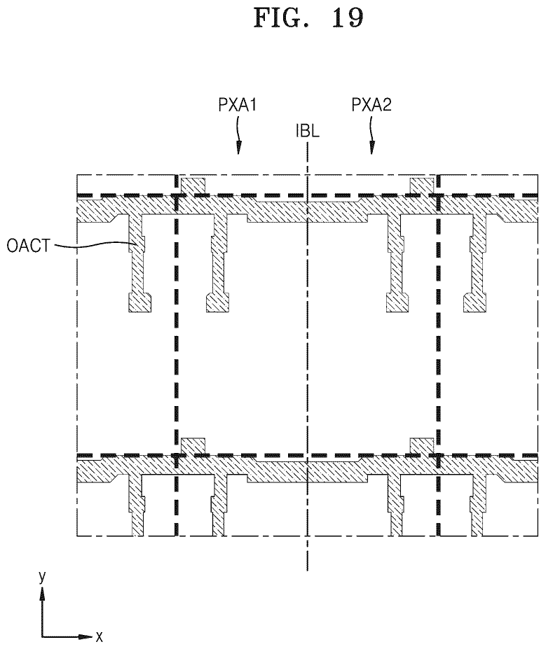

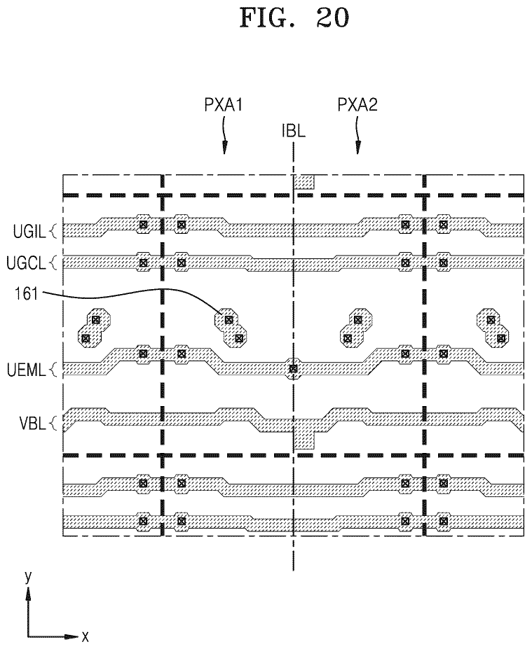

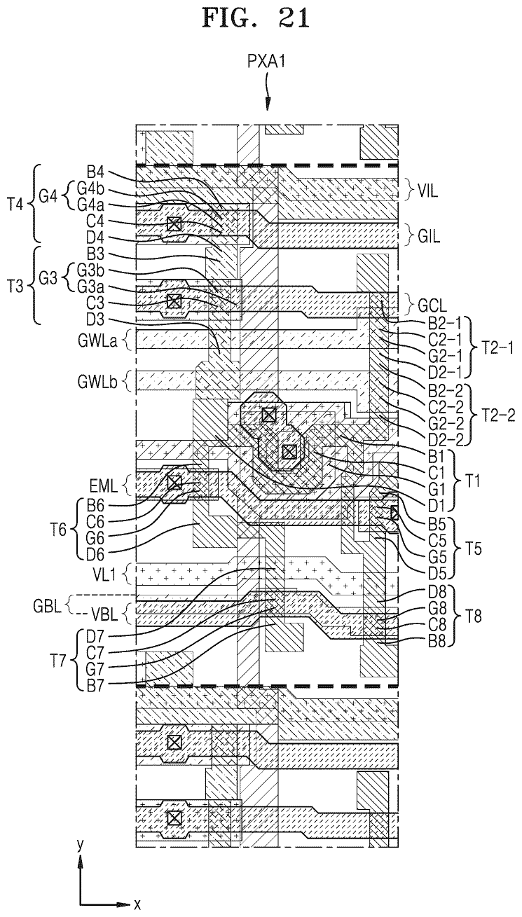

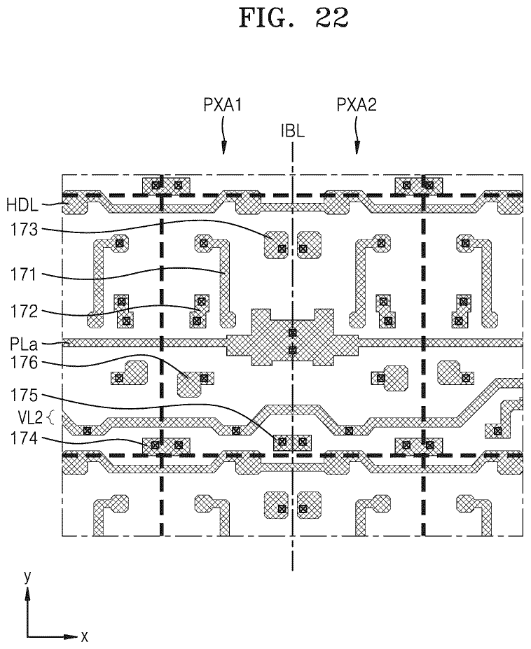

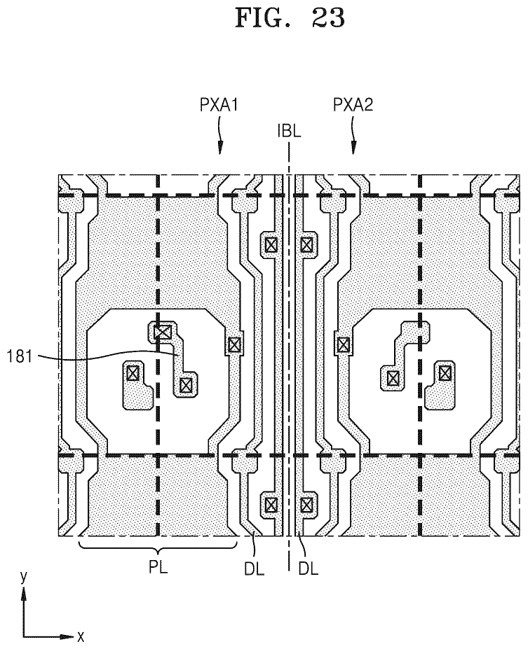

FIGS. 15 to 24 are each an arrangement view schematically illustrating, by layer, devices arranged in a pixel circuit of a display apparatus according to one or more embodiments. FIG. 21 is a plan view illustrating an overlap of devices of FIGS. 15 to 20.

As the same devices are arranged at each layer of the first pixel area PXA1 and the second pixel area PXA2, the embodiments will be described by focusing on devices of a pixel circuit arranged in the first pixel area PXA1 for convenience.

Referring to FIGS. 13, 14, and 15, the bottom metal layer BML may be arranged on the substrate 100. The bottom metal layer BML may include a portion arranged in each of the first pixel area PXA1 and the second pixel area PXA2 (hereinafter, “main portion BML-m”). Each main portion BML-m may be connected to other portions extending in the x direction and/or the y direction (hereinafter, “branch portion BML-b”).

Referring to FIGS. 13, 14, and 16, the buffer layer 111 may be arranged on the bottom metal layer BML, and the silicon semiconductor pattern SACT may be arranged on the buffer layer 111. The silicon semiconductor pattern SACT may include a silicon-based material, for example, polycrystalline silicon.

The silicon semiconductor pattern SACT may have various curved shapes. The silicon semiconductor pattern SACT may include a channel area of each of the first transistor T1, the second transistor T2, the fifth transistor T5, the sixth transistor T6, the seventh transistor T7, and the eighth transistor T8, and a first area and a second area arranged at both sides of the channel area. One of the first area and the second area may be a source area, and the other may be a drain area.

Referring to FIG. 21, the silicon semiconductor pattern SACT may include the channel area C1, the first area B1, and the second area D1 of the first transistor T1, the channel area C2-1, the first area B2-1 and the second area D2-1 of the 2-1 transistor T2-1, the channel area C2-2, the first area B2-2, and the second area D2-2 of the 2-2 transistor T2-2, the channel area C5, the first area B5, and the second are D5 of the fifth transistor T5, the channel area C6, the first area B6, and the second area D6 of the sixth transistor T6, and the channel area C7, the first area B7, and the second area D7 of the seventh transistor T7. The channel area C8, the first area B8, and the second area D8 of the eighth transistor T8 may be further included. As the channel area C1 of the first transistor T1 has a curved shape that may extend long, the driving range of the gate voltage applied to the gate electrode may be wide. The channel area C1 may have various shapes including those resembling “C,” “2,” “S,” “M,” and “W.”

At least a part of the silicon semiconductor pattern SACT may overlap the bottom metal layer BML. For example, the channel area C1 of the first transistor T1 included in the silicon semiconductor pattern SACT may overlap the main portion BML-m, which is a part of the bottom metal layer BML.

Referring to FIGS. 13, 14, and 17, the first gate-insulating layer 112 covering the silicon semiconductor pattern SACT may be arranged on the buffer layer 111, the gate electrode G1 of the first transistor T1 may be arranged in the form of island on the first gate-insulating layer 112, and the 1-1 gate line GWLa, the 1-2 gate line GWLb, the first lower fifth gate line SEML1, the second lower fifth gate line SEML2, the lower second gate line SGIL, and the fourth gate line GBL may be arranged extending in the x direction.

The gate electrode G1 of the first transistor T1 may be the first capacitor electrode CE1, which is the first electrode of the first capacitor Cst. The gate electrode G2-1 of the 2-1 transistor T2-1 and the gate electrode G2-2 of the 2-2 transistor T2-2 may respectively be portions of the 1-1 gate line GWLa and the 1-2 gate line GWLb that intersect with (overlap) the silicon semiconductor pattern SACT. The gate electrode G5 of the fifth transistor T5 and the gate electrode G6 of the sixth transistor T6 may respectively be portions of the first lower fifth gate line SEML1 and the second lower fifth gate line SEML2 that intersect with the silicon semiconductor pattern SACT. The gate electrode G7 of the seventh transistor T7 may be a portion of the fourth gate line GBL intersecting with the silicon semiconductor pattern SACT. The gate electrode G8 of the eighth transistor T8 may be a portion of the fourth gate line GBL intersecting with the silicon semiconductor pattern SACT.

Referring to FIGS. 13, 14, and 18, the first interlayer insulating layer 113 may be arranged on the first gate-insulating layer 112, and the node initialization voltage line VIL, the first initialization voltage line VL1 the electrode voltage line HL, and the lower third gate line SGCL may be arranged and extend in the x direction on the first interlayer insulating layer 113.

A part of the electrode voltage line HL may be the second capacitor electrode CE2, which is the second electrode of the first capacitor Cst, and may cover the first capacitor electrode CE1 of the first capacitor Cst. The second capacitor electrodes CE2 of the first capacitors Cst arranged in the first pixel area PXA1 and the second pixel area PXA2 may be connected to each other by the electrode voltage line HL. The opening SOP may be formed in the second capacitor electrode CE2 of the first capacitor Cst.

Referring to FIGS. 13, 14, and 19, the second interlayer insulating layer 114 may be arranged on the first interlayer insulating layer 113, and the oxide semiconductor pattern OACT may be arranged on the second interlayer insulating layer 114. The oxide semiconductor pattern OACT of the first pixel area PXA1 may be connected and integrated with the oxide semiconductor pattern OACT of the second pixel area PXA2. The oxide semiconductor pattern OACT may include the channel area of each of the third transistor T3 and the fourth transistor T4, and the first area and the second arranged on both sides of the channel area. One of the first area and the second area may be a source area, and the other may be a drain area. The source area and the drain area of the semiconductor pattern may respectively correspond to the first terminal (or second terminal) and the second terminal (or first terminal) of the transistor described in relation to FIG. 3. In some cases, the source area or the drain area may be translated as the source electrode or the rain electrode of the transistor.

Referring to FIG. 21, the oxide semiconductor pattern OACT may include the channel area C3, the first area B3, and the second area D3 of the third transistor T3, the channel area C4, the first area B4, and the second area D4 of the fourth transistor T4.

Referring to FIGS. 13, 14, and 20, the second gate-insulating layer 115 may be arranged on the second interlayer insulating layer 114, the connection electrode 161 may be arranged on the second gate-insulating layer 115, and the upper second gate line UGIL, the upper third gate line UGCL, the upper fifth gate line UEML, and the bias voltage line VBL may be arranged and extend in the x direction.

The upper second gate line UGIL and the lower second gate line SGIL may overlap each other. The upper second gate line UGIL may be electrically connected to the lower second gate line SGIL through a contact hole. The upper third gate line UGCL may be electrically connected to the lower third gate line SGCL through a contact hole. The upper fifth gate line UEML may overlap the first lower fifth gate line SEML1 and the second lower fifth gate line SEML2. The upper fifth gate line UEML may be electrically connected to the first lower fifth gate line SEML1 and the second lower fifth gate line SEML2 through a contact hole. The connection electrode 161 may be connected to the gate electrode G1 of the first transistor T1 through a contact hole. In this regard, the contact hole may be arranged apart from an edge of the opening SOP in the opening SOP of the second capacitor electrode CE2 of the first capacitor Cst.

The gate electrode of the third transistor T3 may be a part of the upper third gate line UGCL and the lower third gate line SGCL that cross, or overlap, the oxide semiconductor pattern OACT. The gate electrode of the third transistor T3 may include the lower gate electrode G3a, which is a part of the lower third gate line SGCL and the upper gate electrode G3b, which is a part of the upper third gate line UGCL. The gate electrode of the fourth transistor T4 may be a part of the upper second gate line UGIL and the lower second gate line SGIL that crosses, or overlaps, the oxide semiconductor pattern OACT. The gate electrode of the fourth transistor T4 may include the lower gate electrode G4a, which is a part of the lower second gate line SGIL and an upper gate electrode G4b, which is a part of the upper second gate line UGIL. That is, the third transistor T3 and the fourth transistor T4 may have a double gate structure including a gate electrode both on and under the oxide semiconductor pattern OACT.

Referring to FIGS. 13, 14, and 22, the third interlayer insulating layer 116 may be arranged on the second gate-insulating layer 115, and on the third interlayer insulating layer 116, a sub-first power voltage line PLa, a horizontal data line HDL, and the second initialization voltage line VL2 may be arranged and extend in the x direction. In addition, first to sixth connection electrodes 171 to 176 may be arranged on the third interlayer insulating layer 116.

One end of the first connection electrode 171 may be in contact with the oxide semiconductor pattern OACT through a contact hole, and may be electrically connected to the oxide semiconductor pattern OACT. One end of the first connection electrode 171 may be electrically connected to the first area B3 of the third transistor T3 and the second area D4 of the fourth transistor T4. Another end of the first connection electrode 171 may be electrically connected to the connection electrode 161 through a contact hole. The first connection electrode 171 may be electrically connected to the gate electrode G1 of the first transistor T1 through the connection electrode 161.

The second connection electrode 172 may be electrically connected to the second area D1 of the first transistor T1 and the first area B6 of the sixth transistor T6 through a contact hole. The second connection electrode 172 may be electrically connected to the second area D3 of the third transistor T3 through a contact hole.

The third connection electrode 173 may be electrically connected to the first area B2-1 of the 2-1 transistor T2-1 through a contact hole.

The fourth connection electrode 174 may be electrically connected to the first area B4 of the fourth transistor T4. The fourth connection electrode 174 may be electrically connected to the node initialization voltage line VIL through a contact hole. The node initialization voltage line VIL may be electrically connected to the first area B4 of the fourth transistor T4 through the fourth connection electrode 174.

The fifth connection electrode 175 may be electrically connected to the first are B8 of the eighth transistor T8 through a contact hole. The fifth connection electrode 175 may be electrically connected to the bias voltage line VBL through a contact hole.

The sixth connection electrode 176 may be electrically connected to the second area D6 of the sixth transistor T6 through a contact hole passing through the insulating layers (112, 113, 114, and 116).

The sub-first power voltage line PLa may be electrically connected to the first area B5 of the fifth transistor T5 through a contact hole. The sub-first power voltage line PLa may be electrically connected to the electrode voltage line HL through a contact hole.

The second initialization voltage line VL2 may be electrically connected to the first area B7 of the seventh transistor T7 through a contact hole. In one or more embodiments, a pixel corresponding to the pixel circuit arranged in the first pixel area PXA1 may be a green pixel.

Referring to FIGS. 13, 14, and 23, the second organic insulating layer 123 may be arranged on the first organic insulating layer 121, the connection electrode may be arranged on the second organic insulating layer 123, and the data line DL and the first power supply line PL may be arranged and extend in the y direction. Various conductive layers may be further arranged on the second organic insulating layer 123.

Some of the data lines DL may be electrically connected to the horizontal data line HDL through a contact hole. Some of the data lines DL may be electrically connected to the third connection electrode 173 through a contact hole and may be electrically connected to the first area B2-1 of the 2-1 transistor T2-1.

The first power supply line PL may be electrically connected to the sub-first power voltage line PLa through a contact hole. The first power supply line PL extending in the y direction may be connected to the sub-first power voltage line PLa extending in the x direction to have a mesh structure.

The connection electrode 181 may be electrically connected to the sixth connection electrode 176 through a contact hole and may be electrically connected to the second area D6 of the sixth transistor T6.

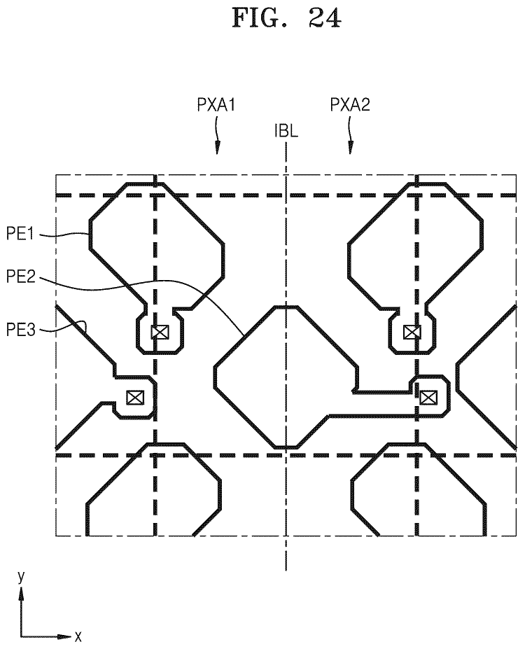

Referring to FIGS. 13, 14, and 24, the pixel electrode 210 may be arranged on the second organic insulating layer 123. FIG. 24 illustrates a pixel electrode PE1 of the first pixel, a pixel electrode PE2 of the second pixel, and a pixel electrode PE3 of the third pixel. In one or more embodiments, the first pixel may be a green pixel, the second pixel may be a red pixel, and the third pixel may be a blue pixel.

The bank layer 140 may be arranged on the pixel electrode 210. The opening 140OP corresponding to the emission area of each pixel may be defined in the bank layer 140. The emission layer 220 and the opposite electrode 230 may be arranged in the opening 140OP of the bank layer 140.

The display apparatus according to the embodiment may be applied to various electronic devices. An electronic device according to an embodiment of the present disclosure may include the display apparatus (e.g., the display apparatus of FIGS. 1A and 1B) described above, and may further include modules or apparatuses having additional functions in addition to the display apparatus.

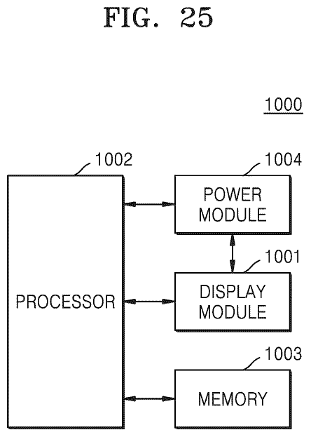

FIG. 25 is a block diagram of an electronic device according to an embodiment.

Referring to FIG. 25, an electronic device 1000 according to an embodiment may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), and a controller.

The memory 1003 may store data information necessary for the operation of the processor 1002 or the display module 1001. When the processor 1002 executes an application stored in the memory 1003, an image data signal and/or an input control signal may be transmitted to the display module 1001, and the display module 1001 may process a signal received and output image information through a display screen.

The power module 1004 may include a power supply module such as a power adapter or a battery device, and a power conversion module that converts the power supplied by the power supply module to generate power necessary for the operation of the electronic device 1000.

At least one of the components of the electronic device 1000 described above may be included in the display apparatus according to the embodiments described above. In addition, a part among the individual modules functionally included in one module may be included in the display apparatus, and another part may be provided separately from the display apparatus. For example, the display apparatus may include the display module 1001, and the processor 1002, the memory 1003, and the power module 1004 may be provided in the form of other apparatuses within the electronic device 1000 except for the display apparatus.

In an embodiment, the display module 1001 included in the display apparatus may drive based on the image data signal and the input control signal received from the processor 1002.

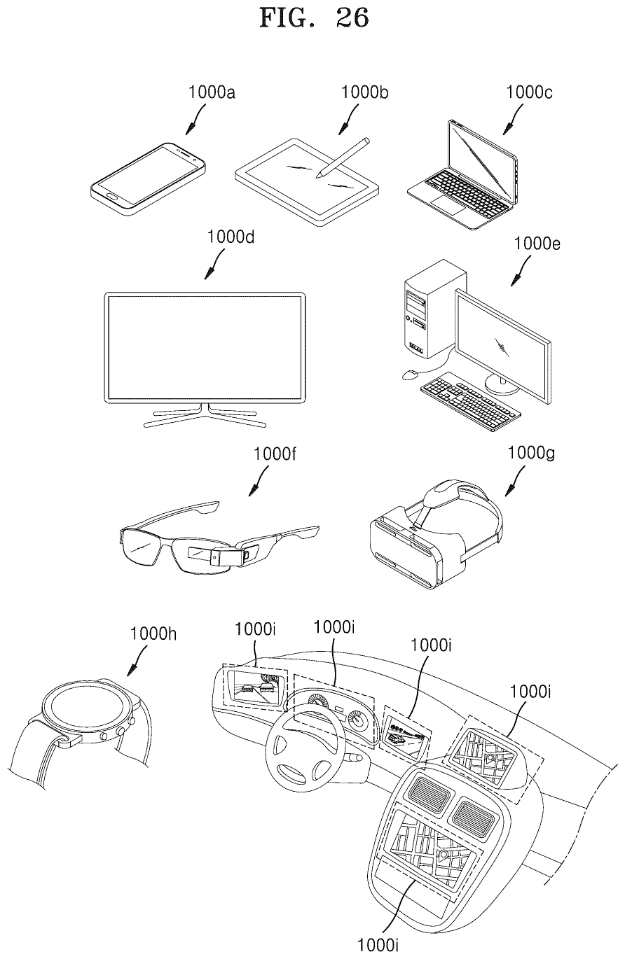

FIG. 26 is schematic diagrams of electronic devices according to various embodiments.

Referring to FIG. 26, various electronic devices to which display apparatuses according to embodiments are applied may include not only image display electronic devices such as a smart phone 1000a, a tablet PC 1000b, a laptop 1000c, a TV 1000d, and a desk monitor 1000e, but also a wearable electronic device including display modules such as smart glasses 1000f, a head mounted display 1000g, and a smart watch 1000h, and a vehicle electronic device 1000i including a dashboard, a center fascia, and display modules such as a CID (Center Information Display) and a room mirror display disposed in the dashboard.

According to one or more embodiments, a display apparatus with improved display quality may be provided. However, the scope of the disclosure is not limited to the above mentioned effects.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A pixel comprising:
a light-emitting diode;
a first transistor connected between a first voltage line and the light-emitting diode, and configured to control a current supplied to the light-emitting diode;
a second transistor connected between a data line and a first node connected to a first terminal of the first transistor, and comprising a 2-1 transistor connected between the data line and a fourth node, and a 2-2 transistor in series with the 2-1 transistor and connected between the fourth node and the first node;
a third transistor connected between a second node connected to a gate of the first transistor and a third node connected to a second terminal of the first transistor;
a fifth transistor connected between the first voltage line and the first node; and
a sixth transistor connected between the third node and the light-emitting diode.

2. The pixel of claim 1, wherein a gate-on voltage is supplied to a gate of the 2-1 transistor at some time while a gate-on voltage is supplied to a gate of the 2-2 transistor.

3. The pixel of claim 1, wherein a gate-on voltage of a second level is supplied to a gate of the third transistor at some time while a gate-off voltage of a first level is supplied a gate of the fifth transistor and to a gate of the sixth transistor, and at some time while a gate-on voltage of the first level is supplied to a gate of the 2-1 transistor to a gate of the 2-2 transistor.

4. The pixel of claim 3, wherein the gate of the 2-1 transistor is connected to a 1-1 gate line, and the gate of the 2-2 transistor is connected to a 1-2 gate line.

5. The pixel of claim 4, wherein the gate of the fifth transistor and the gate of the sixth transistor are connected to a fifth gate line.

6. The pixel of claim 5, further comprising an eighth transistor configured to supply a bias voltage to the first node,
wherein a gate of the eighth transistor is connected to a fourth gate line.

7. The pixel of claim 6, further comprising a seventh transistor connected between a pixel electrode of the light-emitting diode and a second voltage line,
wherein a gate of the seventh transistor is connected to the fourth gate line.

8. The pixel of claim 7, further comprising:
a first capacitor connected between the first voltage line and the second node; and
a fourth transistor connected between the second node and a third voltage line.

9. The pixel of claim 8, further comprising a second capacitor connected between the first voltage line and the fourth node.

10. The pixel of claim 8, wherein the fourth transistor is connected to a second gate line, and
wherein the third transistor is connected to a third gate line.

11. A display apparatus comprising pixels, wherein the pixels comprise:
a light-emitting diode;
a first transistor connected between a first voltage line and the light-emitting diode, and configured to control a current supplied to the light-emitting diode;
a second transistor connected between a data line and a first node connected to a first terminal of the first transistor, and comprising:
a 2-1 transistor connected between the data line and a fourth node, and connected to a 1-1 gate line for providing a 1-1 gate signal; and
a 2-2 transistor in series with the 2-1 transistor, connected between the fourth node and the first node, and connected to a 1-2 gate line for providing a 1-2 gate signal;
a third transistor connected between a second node connected to a gate of the first transistor and a third node connected to a second terminal of the first transistor;
a fifth transistor connected between the first voltage line and the first node; and
a sixth transistor connected between the third node and the light-emitting diode.

12. The display apparatus of claim 11, wherein the 1-2 gate signal comprises a signal temporally shifted from the 1-1 gate signal.

13. The display apparatus of claim 11, wherein the pixels comprise:
a first capacitor connected between the first voltage line and the second node;
an eighth transistor configured to supply a bias voltage to the first node;
a seventh transistor connected between a pixel electrode of the light-emitting diode and a second voltage line; and
a fourth transistor connected between the second node and a third voltage line.

14. The display apparatus of claim 13, wherein the pixels further comprise a second capacitor connected between the first voltage line and the fourth node.

15. The display apparatus of claim 13, wherein a gate of the fifth transistor and a gate of the sixth transistor are connected to a fifth gate line for transmitting a fifth gate signal, and
wherein a gate of the eighth transistor and a gate of the seventh transistor are connected to a fourth gate line for transmitting a fourth gate signal.

16. The display apparatus of claim 15, wherein the fourth transistor is connected to a second gate line for transmitting a second gate signal, and
wherein the third transistor is connected to a third gate line for transmitting a third gate signal.

17. The display apparatus of claim 16, further comprising a gate-driving circuit for outputting the fifth gate signal of a gate-off voltage to the fifth gate line in a non-emission section of a frame section comprising an emission section and the non-emission section, for outputting the third gate signal of a gate-on voltage to the third gate line in a first period of the non-emission section, for outputting a 1-1 gate signal of a gate-on voltage to the 1-1 gate line in a second period during the first period, and for outputting a 1-2 gate signal of a gate-on voltage to the 1-2 gate line in a third period during the first period.

18. The display apparatus of claim 17, wherein the second period and the third period at least partially temporally overlap.

19. An electronic device comprising a display apparatus, wherein the display apparatus comprises;
a light-emitting diode;
a first transistor connected between a first voltage line and the light-emitting diode, and configured to control a current supplied to the light-emitting diode;
a second transistor connected between a data line and a first node connected to a first terminal of the first transistor, and comprising a 2-1 transistor connected between the data line and a fourth node, and a 2-2 transistor in series with the 2-1 transistor and connected between the fourth node and the first node;
a third transistor connected between a second node connected to a gate of the first transistor and a third node connected to a second terminal of the first transistor;
a fifth transistor connected between the first voltage line and the first node; and
a sixth transistor connected between the third node and the light-emitting diode.

20. The electronic device of claim 19, further comprising:
a display module;
a processor;
a power module; and
a memory,
wherein the display apparatus includes one of the display module, the processor, the power module, or the memory.
